(19) United States
(12) Patent Application Publication
(10) Pub. No.: US 2025/0206915 A1
(43) Pub. Date: Jun. 26, 2025

(54) RESIN COMPOSITION, PREPREG, RESIN SHEET, LAMINATE, METAL FOIL-CLAD LAMINATE, AND PRINTED WIRING BOARD

(71) Applicant: MITSUBISHI GAS CHEMICAL COMPANY, INC., Tokyo (JP)

(72) Inventors: Tatsuro TAKAMURA, Tokyo (JP); Sayaka ITO, Tokyo (JP); Shohei YAMAGUCHI, Tokyo (JP); Shunya SAHARA, Tokyo (JP); Naoki KASHIMA, Tokyo (JP); Takaaki OGASHIWA, Tokyo (JP)

(73) Assignee: MITSUBISHI GAS CHEMICAL COMPANY, INC., Tokyo (JP)

(21) Appl. No.: 18/849,811

(22) PCT Filed: Mar. 24, 2023
(86) PCT No.: PCT/JP2023/011741

§ 371 Date: Sep. 23, 2024

(30) Foreign Application Priority Data
Mar. 31, 2022 (JP) 2022-057895

(51) Int. Cl. C08K 3/22; C08J 5/24; C08K 5/521; C08K 5/524; C08K 5/5373; C08K 5/5399; C08L 65/02

(52) U.S. Cl. CPC C08K 3/22; C08J 5/24; C08K 5/521; C08K 5/524; C08K 5/5373; C08K 5/5399; C08L 65/02; C08J 2365/02; C08K 2003/2241; C08K 2201/005; C08L 2203/16; C08L 2203/20

(57) ABSTRACT

A resin composition has a high permittivity and a low dissipation factor, and having a high peel strength of the metal foil, excellent moisture absorption and heat resistance, and favorable thermal characteristics, and suitably used for producing an insulation layer of a printed wiring board; and a prepreg, a resin sheet, a laminate, a metal foil-clad laminate, and a printed wiring board obtainable by using the resin composition. The resin composition contains: (A) a dielectric powder, (B) an aromatic phosphorus compound, and (C) a thermosetting resin.

### TECHNICAL FIELD

The present invention relates to a resin composition, a prepreg, a resin sheet, a laminate, a metal foil-clad laminate, and a printed wiring board.

### BACKGROUND ART

In recent years, signal bands for information and telecommunication device such as PHS, and mobile phones, and CPU clock time of computers have reached the GHz band, and thus the frequency has been higher. A dielectric loss of an electrical signal is proportionate to the product of a square root of a relative permittivity and a dissipation factor of an insulation layer forming a circuit, and a frequency of the electrical signal. For this reason, the higher a frequency of a signal used, the greater a dielectric loss becomes. An increase in the dielectric loss dampens an electrical signal to undermine the reliability of the signal. It is necessary for preventing this to select a material having low permittivity and dissipation factor for an insulation layer.

On the other hand, for an insulation layer of a high frequency circuit, there are demands for formation of a delay circuit, impedance matching of a wiring board in a low impedance circuit, a finer wiring pattern, and a circuit more complex with a substrate having a built-in capacitor, and there is a case where an insulation layer with a higher permittivity is required. For this reason, electronic components in which an insulation layer having a high permittivity and a low dissipation factor is used have been proposed (e.g., Patent Document 1). An insulation layer having a high permittivity and a low dissipation factor is formed by dispersing a filler such as a ceramic powder and an insulated metal powder in a resin.

### CITATION LIST

### Patent Document

Patent Document 1: Japanese Patent Laid-Open No. 2000-91717

### SUMMARY OF INVENTION

### Technical Problem

In general, for increasing the relative permittivity of an insulation layer, a filler having a high relative permittivity is required to be blended, however a dissipation factor also simultaneously increases, thereby posing the problem of a higher transmission loss of a higher frequency signal. Accordingly, there is a need for a material keeping a high relative permittivity and simultaneously having a lower dissipation factor.

Additionally, the filler used for producing the insulation layer having a high permittivity and a low dissipation factor forms voids depending on the filler blended, and sometimes causes delamination when producing a laminate. For this reason, such a filler poses the problem of the poor thermal characteristics and dielectric characteristics (high permittivity and low dissipation factor) in a printed wiring board and the like.

Further, such a filler and a resin pose the problem of causing the poor dielectric characteristics and productivity of a printed wiring board, when have high moisture absorption properties. When an insulation layer has low moisture absorption and heat resistance, moisture contained in the insulation layer evaporates during reflow operation, thereby forming voids, and causing delamination during production of a laminate. For this reason, in the field of electronic materials where high reliability is required, the insulation layer is demanded to have excellent moisture absorption and heat resistance.

The insulation layer is demanded to have a sufficient peel strength of the metal foil (e.g., copper foil peel strength) when incorporated into a metal foil-clad laminate.

The present invention has been made to solve the problems described above and has aimed to provide a resin composition having a high permittivity and a low dissipation factor, and having a high peel strength of the metal foil, excellent moisture absorption and heat resistance, and excellent thermal characteristics, and suitably used for producing an insulation layer of a printed wiring board; and a prepreg, a resin sheet, a laminate, a metal foil-clad laminate, and a printed wiring board obtainable by using the resin composition.

### Solution to Problem

The present inventors have conducted extensive studies to solve the above problems posed by the conventional technology, and have found that a specific resin composition can solve the above problems, whereby the present invention has been accomplished.

Specifically, the present invention is as follows.

[1]A resin composition containing:
(A) a dielectric powder,
(B) an aromatic phosphorus compound, and
(C) a thermosetting resin.
   [2] The resin composition according to [1], wherein the dielectric powder (A) contains one or more selected from the group consisting of titanium dioxide, barium titanate, calcium titanate, and strontium titanate.
   [3] The resin composition according to [1] or [2], wherein a median particle size of the dielectric powder (A) is 0.1 to 5 μm.
   [3] The resin composition according to any of [1] to [3], wherein a content of the dielectric powder (A) is 50 to 500 parts by mass, based on 100 parts by mass of a total resin solid content in the resin composition.
   [4] The resin composition according to any of [1] to [4], wherein the aromatic phosphorus compound (B) contains one or more selected from the group consisting of phosphaphenanthrene compounds, aromatic phosphorus compounds represented by the following formula (1), aromatic phosphorus compounds represented by the following formula (2), aromatic phosphorus compounds represented by the following formula (3), and aromatic phosphorus compounds represented by the following formula (4):

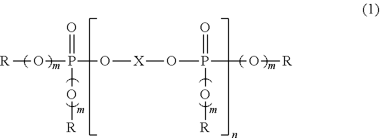

wherein R each independently represents a hydrogen atom, an alkyl group having 1 to 30 carbon atoms, or an aryl group having 6 to 30 carbon atoms, X represents a divalent organic group, m is each independently 0 or 1, and n is 0 to 5, provided that at least one R in the formula (1) is an aryl group having 6 to 30 carbon atoms;

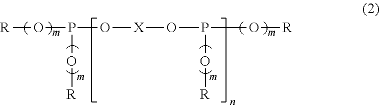

wherein R each independently represents a hydrogen atom, an alkyl group having 1 to 30 carbon atoms, or an aryl group having 6 to 30 carbon atoms, X represents a divalent organic group, m is each independently 0 or 1, and n is 0 to 5, provided that at least one R in the formula (2) is an aryl group having 6 to 30 carbon atoms;

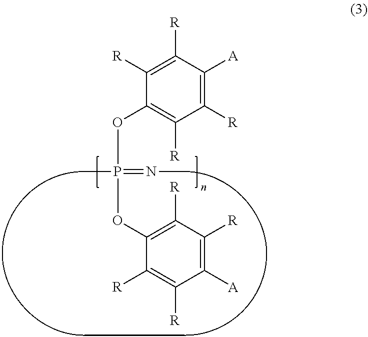

wherein A each independently represents a hydrogen atom, a hydroxy group, a cyano group, an amino group, a carboxy group, a glycidyloxy group, a para-hydroxyphenyl dimethyl group, a para-glycidyloxyphenyl dimethyl group, a para-hydroxyphenyl sulfone group, a para-glycidyloxyphenyl sulfone group, an alkyl group having 1 to 30 carbon atoms, an alkenyl group having 2 to 30 carbon atoms, or an aryl group having 6 to 30 carbon atoms, R each independently represents a hydrogen atom, an alkyl group having 1 to 30 carbon atoms, or an aryl group having 6 to 30 carbon atoms, and n represents an integer of 3 to 15;

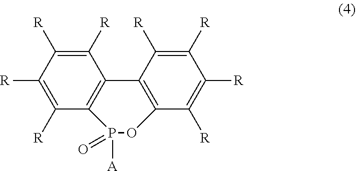

wherein A represents a hydrogen atom, a hydroxy group, a cyano group, an amino group, a carboxy group, a glycidyloxy group, a para-hydroxyphenyl dimethyl group, a para-glycidyloxyphenyl dimethyl group, a para-hydroxyphenyl sulfone group, a para-glycidyloxyphenyl sulfone group, an alkyl group having 1 to 30 carbon atoms, an alkenyl group having 2 to 30 carbon atoms, or an aryl group having 6 to 30 carbon atoms, and R each independently represents a hydrogen atom, an alkyl group having 1 to 30 carbon atoms, or an aryl group having 6 to 30 carbon atoms.
   [6] The resin composition according to [5], wherein the aromatic phosphorus compound represented by the formula (1) contains one or more selected from the group consisting of aromatic phosphorus compounds represented by the following formula (6) and aromatic phosphorus compounds represented by the following formula (8):

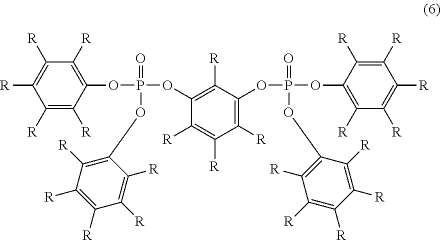

wherein R each independently represents a hydrogen atom, an alkyl group having 1 to 30 carbon atoms, or an aryl group having 6 to 30 carbon atoms;

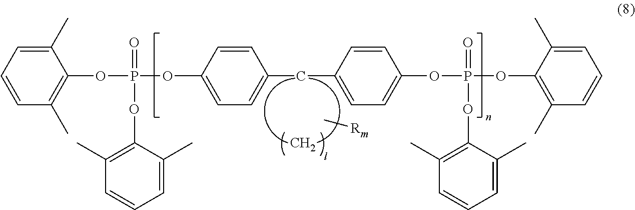

wherein R represents an alkyl group having 1 to 4 carbon atoms, 1 represents an integer of 3 to 11, m represents an integer of 0 to 22, and n represents an integer of 1 to 10.
   [7] The resin composition according to any of [1] to [6], wherein a content of the aromatic phosphorus compound (B) is 1 to 40 parts by mass, based on 100 parts by mass of a resin solid content in the resin composition.
   [8] The resin composition according to any of [1] to [7], wherein the thermosetting resin (C) contains one or more selected from the group consisting of cyanate ester compounds, maleimide compounds, epoxy compounds, phenol compounds, modified polyphenylene ether compounds, alkenyl-substituted nadiimide compounds, oxetane resins, benzoxazine compounds, and compounds having a polymerizable unsaturated group.
   [9] The resin composition according to [8], wherein the maleimide compound contains one or more selected from the group consisting of bis(4-maleimidephenyl)methane, 2,2-bis(4-(4-maleimidephenoxy)-phenyl)propane, bis(3-ethyl-5-methyl-4-maleimidephenyl)methane, maleimide compounds represented by the following formula (11), maleimide compounds represented by the following formula (12), and maleimide compounds represented by the following formula (13):

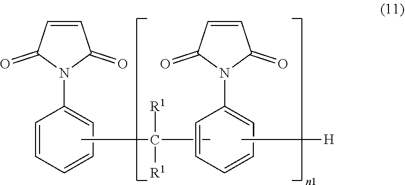

wherein R¹ each independently represents a hydrogen atom or a methyl group, and n1 is an integer of 1 to 10;

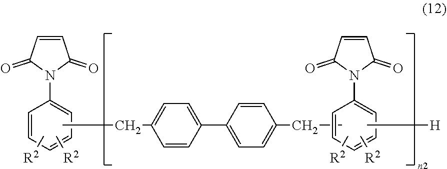

wherein R² each independently represents a hydrogen atom, an alkyl group having 1 to 5 carbon atoms, or a phenyl group, and n2 is an average value and represents 1<n2≤5;

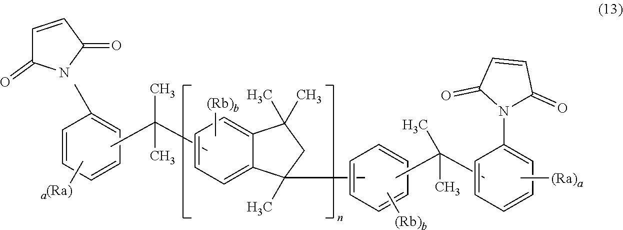

wherein Ra each independently represents an alkyl group, an alkyloxy group or an alkylthio group having 1 to 10 carbon atoms, an aryl group, an aryloxy group or an arylthio group having 6 to 10 carbon atoms, a cycloalkyl group having 3 to 10 carbon atoms, a halogen atom, a nitro group, a hydroxy group, or a mercapto group, q represents an integer of 0 to 4, and when q is an integer of 2 to 4, Ra can be the same or different in the same ring, Rb each independently represents an alkyl group, an alkyloxy group or an alkylthio group having 1 to 10 carbon atoms, an aryl group, an aryloxy group or an arylthio group having 6 to 10 carbon atoms, a cycloalkyl group having 3 to 10 carbon atoms, a halogen atom, a hydroxy group, or a mercapto group, r represents an integer of 0 to 3, and when r is 2 or 3, Rb can be the same or different in the same ring, and n is the average number of repeating units and represents a value of 0.95 to 10.0.
   [10] The resin composition according to [8] or [9], wherein a content of the maleimide compound is 15 to 85 parts by mass, based on 100 parts by mass of a resin solid content in the resin composition.
   [11] The resin composition according to any of [1] to [10], further containing a filler different from the dielectric powder (A).
   [12] The resin composition according to [11], wherein the filler contains one or more selected from the group consisting of silica, alumina, talc, aluminum nitride, boron nitride, boehmite, aluminum hydroxide, zinc molybdate, silicone rubber powder, and silicone composite powder.
   [13] The resin composition according to [11] or [12], wherein a content of the filler is 50 to 300 parts by mass, based on 100 parts by mass of a resin solid content in the resin composition.
   [14] The resin composition according to any of [1] to [13], wherein the resin composition is for a printed wiring board.
   [15]A prepreg, containing:
a base material, and
the resin composition according to any of [1] to [14] penetrating or coating the base material.
   [16]A resin sheet containing the resin composition according to any of [1] to [14].
   [17]A laminate containing one or more selected from the group consisting of the prepreg according to [15], and the resin sheet according to [16].
   [18]A metal foil-clad laminate, containing:
the laminate according to [17], and
a metal foil disposed on one side or each of both sides of the laminate.
   [19]A printed wiring board, containing an insulation layer, and a conductor layer disposed on one side or each of both sides of the insulation layer, wherein the insulation layer contains a cured product of the resin composition according to any of [1] to [14].

### Advantageous Effects of Invention

The resin composition of the present invention can accordingly provide a resin composition having a high permittivity and a low dissipation factor, and having a high peel strength of the metal foil, excellent moisture absorption and heat resistance, and excellent thermal characteristics, and suitably used for producing an insulation layer of a printed wiring board; and a prepreg, a resin sheet, a laminate, a metal foil-clad laminate, and a printed wiring board obtainable by using the resin composition.

### DESCRIPTION OF EMBODIMENTS

Hereinafter, embodiments to carry out the present invention (hereinafter, referred to as the “present embodiment”) will be described in more detail. The following present embodiments are examples to illustrate the present invention and do not intend to limit the present invention to the contents below. The present invention can be carried out with appropriate modifications within the scope of the spirit thereof.

In the present embodiments, the “resin solid content” or the “resin solid content in the resin composition” refers to the resin components of the resin composition, excluding dielectric powder (A), the filler, additives (a silane coupling agent, a wetting and dispersing agent, a curing accelerator, and other components) and a solvent, unless otherwise noticed. The “100 parts by mass of the resin solid content” or the “100 parts by mass of the total resin solid content in the resin composition” means that the total amount of the resin components of the resin composition, excluding dielectric powder (A), the filler, additives (a silane coupling agent, a wetting and dispersing agent, a curing accelerator, and other components) and a solvent, is regarded as 100 parts by mass.

### [Resin Composition]

The resin composition of the present embodiment contains: (A) a dielectric powder, (B) an aromatic phosphorus compound, and (C) a thermosetting resin.

In the present embodiments, since the resin composition contains (A) a dielectric powder, (B) an aromatic phosphorus compound, and (C) a thermosetting resin, it is possible to obtain a cured product having a high permittivity and a low dissipation factor, and having a high peel strength of the metal foil, excellent moisture absorption and heat resistance, and favorable thermal characteristics, and suitable for an insulation layer of a printed wiring board. The reason is not clear but the present inventors infer as follows.

Specifically, a cured product of a resin composition containing a dielectric powder tends to usually have excellent heat resistance and electrical properties. However, it is necessary for obtaining such an effect to blend a large amount of the dielectric powder in the resin composition, and an increase in amount of filling of the dielectric powder tends to cause increases in relative permittivity and also dissipation factor. Accordingly, a cured product obtained from such a resin composition tends to have a higher transmission loss of a higher frequency signal.

On the other hand, according to the resin composition of the present embodiment containing dielectric powder (A) and aromatic phosphorus compound (B), a low dissipation factor of aromatic phosphorus compound (B) can suitably inhibit an increase in the dissipation factor caused due to an increase in the amount of filling of dielectric powder (A). Accordingly, a cured product keeping a high relative permittivity and also having a low dissipation factor can be obtained. The resin composition further contains thermosetting resin (C), and thus it is inferred that the glass transition temperature, the rate of thermal expansion, and the peel strength of the metal foil can be suitably inhibited from being deteriorated due to aromatic phosphorus compound (B) contained and a cured product having excellent dynamic characteristics and heat resistance is obtained. However, the mechanism is not limited to this.

Next, each component included in the resin composition will be described in detail.

### <Dielectric Powder (A)>

The resin composition of the present embodiment contains dielectric powder (A). For dielectric powder (A), dielectric powders can be used singly, or two or more thereof can also be used in combination.

The shape of dielectric powder (A) is not particularly limited, and examples include scale-like shapes, spherical shapes, plate-like shapes, and amorphous shapes. The shape of dielectric powder (A) is preferably spherical in view of being more dispersed with aromatic phosphorus compound (B) and thermosetting resin (C) to be described later, obtaining the cured product having more favorable dielectric characteristics (high permittivity and low dissipation factor) and having superior moisture absorption and heat resistance and more favorable thermal characteristics, and obtaining the insulation layer having more favorable peel strength of the metal foil.

The relative permittivity of dielectric powder (A) is preferably 20 or more, and more preferably 25 or more. When a relative permittivity is 20 or more, the insulation layer having a high relative permittivity tends to be obtained. In the present embodiment, the relative permittivity of dielectric powder (A) is the value at 10 GHz measured by the cavity resonator method. In the present embodiment, the relative permittivity of dielectric powder (A) can be calculated using the Bruggeman formula (law of mixture). A specific measurement method of the relative permittivity can be referred to Examples.

The dissipation factor of dielectric powder (A) is preferably 0.015 or less, and more preferably 0.010 or less, and further preferably 0.008 or less. When a dissipation factor is 0.015 or less, the insulation layer having a low dissipation factor tends to be obtained. In the present embodiment, the dissipation factor of dielectric powder (A) is the value at 10 GHz measured by the cavity resonator method. In the present embodiment, the dissipation factor of dielectric powder (A) can be calculated using the Bruggeman formula (law of mixture). A specific measurement method of the dissipation factor can be referred to Examples.

The median particle size (D50) of dielectric powder (A) is preferably 0.1 to 5 μm, and more preferably 0.15 to 3 μm, in view of the dispersibility. In the present embodiment, the median particle size (D50) means the value at which a cumulative volume from smaller particles reaches 50% of the entire volume when a particle size distribution of a predetermined amount of a powder fed in a dispersion medium is measured using a laser diffraction scattering type particle size distribution analyzer. The median particle size (D50) can be calculated by measuring particle size distribution by a laser diffraction scattering method, but a specific measurement method can be referred to examples.

Examples of dielectric powder (A) include titanium monoxide (TiO), barium titanate (BaTiO₃), calcium titanate (CaTiO₃), strontium titanate (SrTiO₃), dititanium trioxide (Ti₂O₃), and titanium dioxide (TiO₂). Of these, dielectric powder (A) preferably contains one or more selected from the group consisting of titanium dioxide, barium titanate, calcium titanate, and strontium titanate in view of having a higher relative permittivity and a more suitable dissipation factor, being more dispersed in aromatic phosphorus compound (B) and thermosetting resin (C), having a lower catalytic activity to thermosetting resin (C), and having superior formability, and more preferably contains strontium titanate in view of having a higher relative permittivity and a further suitable dissipation factor, being still more dispersed in aromatic phosphorus compound (B) and thermosetting resin (C), having a lower catalytic activity to thermosetting resin (C), and having superior formability. Additionally, titanate oxide, dititanium trioxide, and titanium dioxide have a high relative permittivity and a suitable dissipation factor, and are thus preferable as dielectric powder (A).

For strontium titanate, a known compound can be used, and examples include oxides of a Perovskite structure mostly represented by ABO₃. Strontium titanate can contain a compound having a structure represented by (SrO)ₓ·TiO₂ (0.9≤X<1.0, 1.0<X≤1.1). In this compound, a part of Sr can be substituted with other metal elements, and examples of such a metal element include at least one of La (lanthanum), Ba (barium), and Ca (calcium). Also, in this compound, a part of Ti can be substituted with other metal elements, and examples of such a metal element include Zr (zirconium).

For titanium dioxide, those having rutile-type or anatase-type crystal structure are preferable, and those having rutile-type crystal structure are more preferable.

Dielectric powder (A) can be a commercial product. Examples of the commercial product include, as titanium dioxide, STT-30A and EC-300 manufactured by Titan Kogyo, Ltd., AEROXIDE (registered trademark, the same applies hereinafter) TiO₂T805, AEROXIDE TiO₂ NKT90 (these are all product names) manufactured by NIPPON AEROSIL CO., LTD.; as barium titanate, 208108 (product name) manufactured by ALDRICH; as calcium titanate, CT series manufactured by Fuji Titanium Industry Co., Ltd.; as strontium titanate, ST-2 manufactured by KCM Corporation, ST-03 manufactured by SAKAI CHEMICAL INDUSTRY CO., LTD., 396141 manufactured by ALDRICH, ST, HST-1, HPST-1, and HPST-2 manufactured by Fuji Titanium Industry Co., Ltd., SW-100, SW-50C, SW-100C, SW-200C, SW-320C, and SW-350 (these are all product names) manufactured by Titan Kogyo, Ltd.; as dititanium trioxide, STR-100A-LP manufactured by SAKAI CHEMICAL INDUSTRY CO., LTD., and MT-N1 (these are all product names) manufactured by TAYCA CORPORATION.

The content of dielectric powder (A) is preferably 50 to 500 parts by mass, more preferably 60 to 450 parts by mass, and further preferably 70 to 400 parts by mass, based on 100 parts by mass of the total resin solid content in the resin composition. When a content of dielectric powder (A) is within the above range, the dielectric powder is still more dispersed with aromatic phosphorus compound (B) and thermosetting resin (C), and there is a tendency that it is possible to obtain the cured product having further favorable dielectric characteristics (high permittivity and low dissipation factor) and having further excellent moisture absorption and heat resistance, and further favorable thermal characteristics, and the insulation layer having a further favorable peel strength of the metal foil.

### <Aromatic Phosphorus Compound (B)>

The resin composition of the present embodiment contains aromatic phosphorus compound (B).

In the present embodiments, aromatic phosphorus compound (B) is not particularly limited as long as it has a phosphorus atom in its molecule and is aromatic. For aromatic phosphorus compound (B), aromatic phosphorus compounds can be used singly, or two or more thereof can also be used in combination.

Aromatic phosphorus compound (B) preferably contains one or more selected from the group consisting of phosphaphenanthrene compounds, aromatic phosphorus compounds represented by the following formula (1), aromatic phosphorus compounds represented by the following formula (2), aromatic phosphorus compounds represented by the following formula (3), and aromatic phosphorus compounds represented by the following formula (4). These aromatic phosphorus compounds more disperse dielectric powder (A) and are more compatible with thermosetting resin (C), and there is a tendency that it is possible to obtain the cured product having more favorable dielectric characteristics (high permittivity and low dissipation factor) and having superior moisture absorption and heat resistance, and more favorable thermal characteristics, and the insulation layer having a more favorable peel strength of the metal foil.

Examples of the phosphaphenanthrene compound include 9,10-dihydro-9-oxa-10-phosphaphenanthrene10-oxide and 10-(2,5-dihydroxyphenyl)-9,10-dihydro-9-oxa-10-phosphaphenanthrene-10-oxide. The phosphaphenanthrene compound can be a commercial product, and examples include HCA, HCA-HQ, M-Ester, M-Acid, and SANKO (registered trademark)-BCA (all product names, Sanko Co., Ltd.).

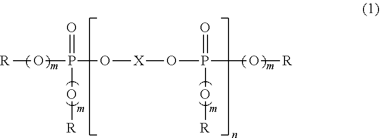

In the formula (1), R each independently represents a hydrogen atom, an alkyl group having 1 to 30 carbon atoms, or an aryl group having 6 to 30 carbon atoms; X represents a divalent organic group; m is each independently 0 or 1; n is 0 to 5; provided that at least one R in the formula (1) is an aryl group having 6 to 30 carbon atoms.

The alkyl group having 1 to 30 carbon atoms in R is preferably an alkyl group having 1 to 20 carbon atoms, and more preferably an alkyl group having 1 to 10 carbon atoms. An alkyl group having 3 or more carbon atoms may be a straight- or branched-chain group. Examples of the alkyl group include a methyl group, an ethyl group, a n-propyl group, an isopropyl group, a n-butyl group, an isobutyl group, a sec-butyl group, a t-butyl group, a n-pentyl group, a neopentyl group, a n-hexyl group, a thexyl group, a n-heptyl group, a n-octyl group, a n-ethylhexyl group, a n-nonyl group, and a n-decyl group.

The alkyl group having 1 to 30 carbon atoms in R is preferably one or more selected from the group consisting of a methyl group, an ethyl group, a n-propyl group, and a n-butyl group, in view of more dispersing dielectric powder (A) and being more compatible with thermosetting resin (C), and in view of a tendency to be able to obtain the cured product having more favorable dielectric characteristics (high permittivity and low dissipation factor) and having superior moisture absorption and heat resistance, and more favorable thermal characteristics, and the insulation layer having a more favorable peel strength of the metal foil.

The aryl group having 6 to 30 carbon atoms in R is preferably an aryl group having 6 to 20 carbon atoms, and more preferably an aryl group having 6 to 12 carbon atoms. The aryl group may have a substituent. Examples of the substituent include a hydroxy group, a sulfonic acid group; alkyl groups such as a methyl group, an ethyl group, and a propyl group; alkoxy groups such as a methoxy group, an ethoxy group, and a propoxy group; a nitro group; and an acyl group. Examples of the aryl group include a phenyl group, a methylphenyl group (cresyl group), a xylyl group, an isopropylphenyl group, a tert-butylphenyl group, a di-tert-butylphenyl group, a p-cumylphenyl group, a bicyclohexylphenyl group, a phenol group, a cyanophenyl group, a nitrophenyl group, a naphthalene group (naphthyl group), a methylnaphthyl group, a biphenyl group, an anthracene group, a naphthacene group, an anthracyl group, a pyrenyl group, a perylene group, a pentacene group, a benzopyrene group, a chrysene group, a pyrene group, a thiophenyl group, and a triphenylene group.

The aryl group having 1 to 30 carbon atoms in R is preferably one or more selected from the group consisting of a phenyl group, a cresyl group, a xylyl group, and an isopropylphenyl group, in view of more dispersing dielectric powder (A) and being more compatible with thermosetting resin (C), and in view of a tendency to be able to obtain the cured product having more favorable dielectric characteristics (high permittivity and low dissipation factor) and having superior moisture absorption and heat resistance, and more favorable thermal characteristics, and the insulation layer having a more favorable peel strength of the metal foil.

In the formula (1), at least one R represents an aryl group having 6 to 30 carbon atoms, at least two R each preferably represent an aryl group having 6 to 30 carbon atoms, at least three R each more preferably represent an aryl group having 6 to 30 carbon atoms, and at least four R each further preferably represent an aryl group having 6 to 30 carbon atoms.

X being a divalent organic group may have a substituent or may have no substituent. Examples of the substituent include an alkyl group, an alkoxy group, an alkylthio group, an aryl group, an aryloxy group, an arylthio group, a halogen atom, and an aryl halide group. The substituent may be a group in which such substituents are combined, or may be a group in which such a substituent and any hetero atom such as an oxygen atom, a sulfur atom, and a nitrogen atom are combined.

X is preferably a group derived from a divalent arylene group. Examples of the group include a divalent group derived from benzene, a divalent group derived from naphthalene, a divalent group derived from anthracene, and a divalent arylene group represented by the following formula (5). These divalent groups may each have a substituent. For the substituent, the above can be seen. X is preferably any of a divalent group derived from benzene, a divalent group derived from naphthalene, and the divalent arylene group represented by the formula (5), and more preferably a divalent group derived from benzene, in view of more dispersing dielectric powder (A) and being more compatible with thermosetting resin (C), and in view of a tendency to be able to obtain the cured product having more favorable dielectric characteristics (high permittivity and low dissipation factor) and having superior moisture absorption and heat resistance, and more favorable thermal characteristics, and the insulation layer having a more favorable peel strength of the metal foil.

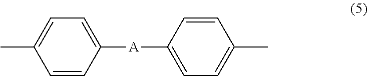

In the formula (5), A represents a direct bond, an alkylene group, an alkylidene group, a cycloalkylene group, a cycloalkylidene group, an arylalkylene group, or an arylalkylidene group.

Examples of the alkylene group include a methylene group, an ethylene group, a trimethylene group, a tetramethylene group, and a hexamethylene group. Of these, an alkylene group having 1 to 5 carbon atoms is preferable.

Examples of the alkylidene group include an ethylidene group and an isopropylidene group.

Examples of the cycloalkylene group include a cyclopentanediyl group, a cyclohexanediyl group, and a cyclooctanediyl group. Of these, a cycloalkylene group having 5 to 10 carbon atoms is preferable.

Examples of the cycloalkylidene group include a cyclohexylidene group, a 3,5,5-trimethylcyclohexylidene group, and a 2-adamantylidene group. Of these, a cycloalkylidene group having 5 to 10 carbon atoms is preferable, and a cycloalkylidene group having 5 to 8 carbon atoms is more preferable.

Examples of the aryl moiety of the arylalkylene group include aryl groups having 6 to 14 carbon atoms, such as a phenyl group, a naphthyl group, a biphenyl group, and an anthryl group. For the alkylene moiety, the above can be seen.

Examples of the aryl moiety of the arylalkylidene group include aryl groups having 6 to 14 carbon atoms, such as a phenyl group, a naphthyl group, a biphenyl group, and an anthryl group. For the alkylene moiety, the above can be seen.

The divalent arylene group represented by the formula (5) is preferably a divalent group derived from any dihydroxy compound such as 2,2′-dihydroxybiphenyl, 2,4′-dihydroxybiphenyl, 3,3′-dihydroxybiphenyl, 3,4′-dihydroxybiphenyl, 4,4′-dihydroxybiphenyl; bisphenol A, bisphenol TMC, 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 1,8-dihydroxynaphthalene, 2,3-dihydroxynaphthalene, 2,6-dihydroxynaphthalene, and 2,7-dihydroxynaphthalene.

At least one of m is preferably 1, two of m are each more preferably 1, three of m are each further preferably 1, and four of m are each furthermore preferably 1.

n is preferably an integer of 1 to 3.

The aromatic phosphorus compound represented by the formula (1) may be a mixture of compounds different in n. In the case of the mixture, n is an average value in the mixture, and is in a range from 0.5 to 3.

The aromatic phosphorus compound represented by the formula (1) preferably contains one or more selected from the group consisting of aromatic phosphorus compounds represented by the formula (6), aromatic phosphorus compounds represented by a formula (7), such as resorcinol bis-diphenyl phosphate and resorcinol bis-dixylenyl phosphate, bisphenol A bis-diphenyl phosphate (BDP), biphenyl bis-diphenyl phosphate, and aromatic phosphorus compounds represented by the formula (8), and more preferably contains one or more selected from the group consisting of aromatic phosphorus compounds represented by the formula (6) and aromatic phosphorus compounds represented by the formula (8), in view of still more dispersing dielectric powder (A) and being still more compatible with thermosetting resin (C), and in view of a tendency to be able to obtain the cured product having further favorable dielectric characteristics (high permittivity and low dissipation factor) and having further excellent moisture absorption and heat resistance, and further favorable thermal characteristics, and the insulation layer having a further favorable peel strength of the metal foil.

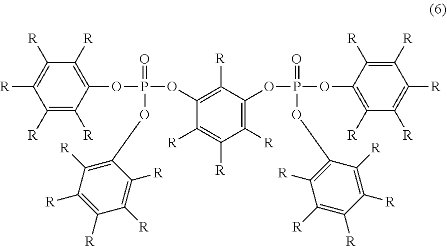

In the formula (6), R each independently represents a hydrogen atom, an alkyl group having 1 to 30 carbon atoms, or an aryl group having 6 to 30 carbon atoms.

For the alkyl group having 1 to 30 carbon atoms and the aryl group having 6 to 30 carbon atoms, the above can be seen. The alkyl group having 1 to 30 carbon atoms is preferably any of a methyl group, an ethyl group, a n-propyl group, and a n-butyl group. The aryl group having 6 to 30 carbon atoms is preferably any of a phenyl group, a cresyl group, a xylyl group, and an isopropylphenyl group.

The aromatic phosphorus compound represented by the formula (6) is preferably the aromatic phosphorus compound represented by the formula (7), in view of more favorably dispersing dielectric powder (A) and being even more compatible with thermosetting resin (C), and in view of a tendency to be able to obtain the cured product having more favorable dielectric characteristics (high permittivity and low dissipation factor) and having superior moisture absorption and heat resistance, and more favorable thermal characteristics, and the insulation layer having a more favorable peel strength of the metal foil.

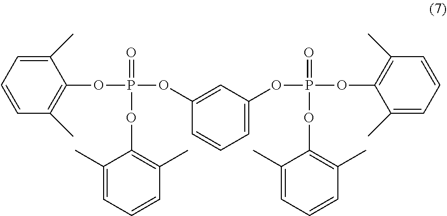 [SMILES: Cc1cccc(C)c1OP(=O)(Oc1cccc(OP(=O)(Oc2c(C)cccc2C)Oc2c(C)cccc2C)c1)Oc1c(C)cccc1C]

The aromatic phosphorus compound represented by the formula (7) can be a commercial product, and examples include PX-200 (product name, Daihachi Chemical Industry Co., Ltd.).

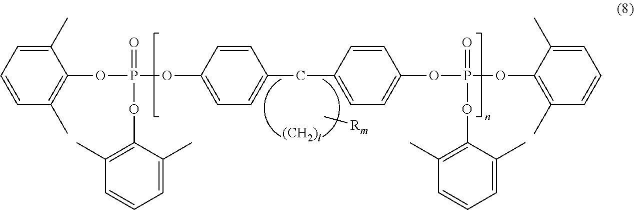

In the formula (8), R represents an alkyl group having 1 to 4 carbon atoms. 1 represents an integer of 3 to 11. m represents an integer of 0 to 22. n represents an integer of 1 to 10.

For the alkyl group having 1 to 4 carbon atoms, the above can be seen. The alkyl group having 1 to 4 carbon atoms is preferably any of a methyl group, an ethyl group, a n-propyl group, and a n-butyl group.

1 is an integer of 3 to 11, and a cyclic alkyl group is formed. Examples of the cyclic alkyl group include cyclohexane, cyclooctane, cyclodecane, and cyclododecane.

m is preferably 0 to 10, more preferably an integer of 0 to 3, and further preferably 0, 2, or 3.

n is preferably an integer of 1 to 5, more preferably an integer of 1 to 3, and further preferably 1 or 2.

The aromatic phosphorus compound represented by the formula (8) is preferably an aromatic phosphorus compound represented by a formula (9), in view of more favorably dispersing dielectric powder (A) and being even more compatible with thermosetting resin (C), and in view of a tendency to be able to obtain the cured product having more favorable dielectric characteristics (high permittivity and low dissipation factor) and having superior moisture absorption and heat resistance, and more favorable thermal characteristics, and the insulation layer having a more favorable peel strength of the metal foil.

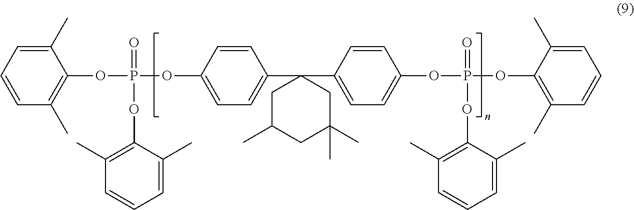

In the formula (9), n represents an integer of 1 to 10. n is preferably an integer of 1 to 3.

The aromatic phosphorus compound represented by the formula (9) can be a commercial product, and examples include SR-3000 (product name, Daihachi Chemical Industry Co., Ltd.).

Aromatic phosphorus compound (B) preferably contains one or more selected from the group consisting of aromatic phosphorus compounds represented by the formula (6) and aromatic phosphorus compounds represented by the formula (8). In this case, 100 mass % of aromatic phosphorus compound (B) contains preferably, in total, 5 mass % or more, more preferably, in total, 10 mass % or more, further preferably, in total, 20 mass % or more, and furthermore preferably, in total, 30 mass % or more of the aromatic phosphorus compounds represented by the formula (6) and the aromatic phosphorus compounds represented by the formula (8). The upper limit is not particularly limited, and is, in total, 100 mass % or less or can be, in total, 90 mass % or less.

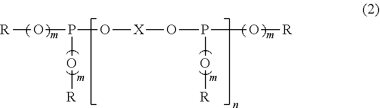

In the formula (2), R each independently represents a hydrogen atom, an alkyl group having 1 to 30 carbon atoms, or an aryl group having 6 to 30 carbon atoms; X represents a divalent organic group. m is each independently 0 or 1; and n is 0 to 5; provided that at least one R in the formula (2) is an aryl group having 6 to 30 carbon atoms.

For R, X, m, and n in the formula (2), and also preferred modes thereof, R, X, m, and n in the aromatic phosphorus compound represented by the formula (1) can be respectively seen.

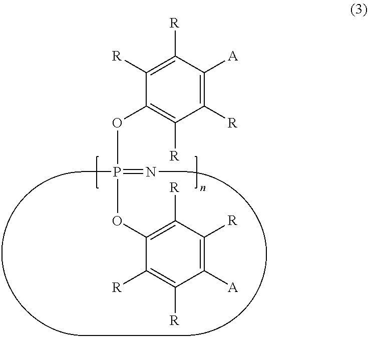

In the formula (3), A each independently represents a hydrogen atom, a hydroxy group, a cyano group, an amino group, a carboxy group, a glycidyloxy group, a para-hydroxyphenyl dimethyl group, a para-glycidyloxyphenyl dimethyl group, a para-hydroxyphenyl sulfone group, a para-glycidyloxyphenyl sulfone group, an alkyl group having 1 to 30 carbon atoms, an alkenyl group having 2 to 30 carbon atoms, or an aryl group having 6 to 30 carbon atoms. R each independently represents a hydrogen atom, an alkyl group having 1 to 30 carbon atoms, or an aryl group having 6 to 30 carbon atoms, and n represents an integer of 3 to 15.

For the alkyl group having 1 to 30 carbon atoms and the aryl group having 6 to 30 carbon atoms, the above can be seen.

The alkyl group having 1 to 30 carbon atoms in A is preferably one or more selected from the group consisting of a methyl group, an ethyl group, a n-propyl group, and a n-butyl group. The aryl group having 6 to 30 carbon atoms in A is preferably one or more selected from the group consisting of a phenyl group, a cresyl group, a xylyl group, and an isopropylphenyl group.

The alkyl group having 1 to 30 carbon atoms in R is preferably one or more selected from the group consisting of a methyl group, an ethyl group, a n-propyl group, and a n-butyl group. The aryl group having 6 to 30 carbon atoms in R is preferably one or more selected from the group consisting of a phenyl group, a cresyl group, a xylyl group, and an isopropylphenyl group.

The alkenyl group having 2 to 30 carbon atoms in A is preferably an alkenyl group having 2 to 20 carbon atoms, and more preferably an alkenyl group having 2 to 10 carbon atoms. The alkenyl group having 2 to 30 carbon atoms may be a straight- or branched-chain group. Examples of the alkenyl group include a vinyl group, an allyl group, a 4-pentenyl group, an isopropenyl group, an isopentenyl group, a 2-heptenyl group, a 2-octenyl group, and a 2-nonenyl group. The alkenyl group having 2 to 30 carbon atoms in A is preferably one or more selected from the group consisting of a vinyl group, an allyl group, and an isopropenyl group. The alkenyl group having 2 to 30 carbon atoms in R is preferably one or more selected from the group consisting of a vinyl group, an allyl group, and an isopropenyl group.

Examples of the aromatic phosphorus compound represented by the formula (2) include hexaphenoxycyclotriphosphazene and pentafluoro(phenoxy)cyclotriphosphazene.

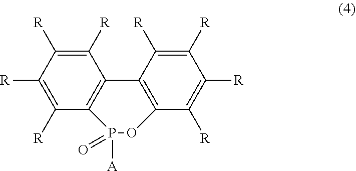

In the formula (4), A represents a hydrogen atom, a hydroxy group, a cyano group, an amino group, a carboxy group, a glycidyloxy group, a para-hydroxyphenyl dimethyl group, a para-glycidyloxyphenyl dimethyl group, a para-hydroxyphenyl sulfone group, a para-glycidyloxyphenyl sulfone group, an alkyl group having 1 to 30 carbon atoms, an alkenyl group having 2 to 30 carbon atoms, or an aryl group having 6 to 30 carbon atoms. R each independently represents a hydrogen atom, an alkyl group having 1 to 30 carbon atoms, or an aryl group having 6 to 30 carbon atoms.

For the alkyl group having 1 to 30 carbon atoms, the alkenyl group having 2 to 30 carbon atoms and the aryl group having 6 to 30 carbon atoms, the above can be seen.

The alkyl group having 1 to 30 carbon atoms in A is preferably one or more selected from the group consisting of a methyl group, an ethyl group, a n-propyl group, and a n-butyl group. The alkenyl group having 2 to 30 carbon atoms in A is preferably one or more selected from the group consisting of a vinyl group, an allyl group, and an isopropenyl group. The aryl group having 6 to 30 carbon atoms in A is preferably one or more selected from the group consisting of a phenyl group, a cresyl group, a xylyl group, and an isopropylphenyl group.

The alkyl group having 1 to 30 carbon atoms in R is preferably one or more selected from the group consisting of a methyl group, an ethyl group, a n-propyl group, and a n-butyl group. The aryl group having 6 to 30 carbon atoms in R is preferably one or more selected from the group consisting of a phenyl group, a cresyl group, a xylyl group, and an isopropylphenyl group.

The content of the aromatic phosphorus compound (B) is preferably 1 to 40 parts by mass, more preferably 2 to 35 parts by mass, further preferably 5 to 32 parts by mass, furthermore preferably 8 to 30 parts by mass, and further preferably 10 to 28 parts by mass, based on 100 parts by mass of the total resin solid content in the resin composition. When a content of aromatic phosphorus compound (B) is within the above range, dielectric powder (A) is even more dispersed, even more compatibility with thermosetting resin (C) is achieved, and there is a tendency that it is possible to obtain the cured product having even further favorable dielectric characteristics (high permittivity and low dissipation factor) and having even further excellent moisture absorption and heat resistance, and even further favorable thermal characteristics, and the insulation layer having an even further favorable peel strength of the metal foil.

The content of aromatic phosphorus compound (B) is preferably 1 to 40 parts by mass, more preferably 2 to 37 parts by mass, further preferably 5 to 36 parts by mass, furthermore preferably 10 to 35 parts by mass, and further preferably 15 to 30 parts by mass, or can be 15 to 25 parts by mass, based on 100 parts by mass of the total of aromatic phosphorus compound (B) and thermosetting resin (C) in the resin composition, in view of being more compatible with aromatic phosphorus compound (B) and thermosetting resin (C), and in view of a tendency to be able to obtain the cured product having further favorable dielectric characteristics (high permittivity and low dissipation factor) and having further excellent moisture absorption and heat resistance, and further favorable thermal characteristics, and the insulation layer having a further favorable peel strength of the metal foil.

### <Thermosetting Resin (C)>

The resin composition of the present embodiment contains thermosetting resin (C).

Thermosetting resin (C) is not particularly limited as long as it is a thermosetting resin or compound. Thermosetting resins (C) can be used singly, or two or more thereof can also be used in combination.

Thermosetting resin (C) preferably contains one or more selected from the group consisting of cyanate ester compounds, maleimide compounds, epoxy compounds, phenol compounds, modified polyphenylene ether compounds, alkenyl-substituted nadiimide compounds, oxetane resins, benzoxazine compounds, and compounds having a polymerizable unsaturated group, more preferably contains one or more selected from the group consisting of maleimide compounds, cyanate ester compounds, phenol compounds, and epoxy compounds, and further preferably contains one or more selected from the group consisting of maleimide compounds, cyanate ester compounds, and epoxy compounds, in view of more dispersing dielectric powder (A) and being more compatible with aromatic phosphorus compound (B), and in view of a tendency to be able to obtain the cured product having more favorable dielectric characteristics (high permittivity and low dissipation factor) and having superior moisture absorption and heat resistance, and more favorable thermal characteristics, and the insulation layer having a more favorable peel strength of the metal foil.

The content of thermosetting resin (C) is preferably 1 to 98.5 parts by mass, more preferably 2 to 97 parts by mass, further preferably 3 to 93.5 parts by mass, furthermore preferably 4 to 90 parts by mass, and further preferably 5 to 87 parts by mass, based on 100 parts by mass of the total resin solid content in the resin composition. When a content of thermosetting resin (C) is within the above range, dielectric powder (A) is even more dispersed, even more compatibility with aromatic phosphorus compound (B) is achieved, and there is a tendency that it is possible to obtain the cured product having even further favorable dielectric characteristics (high permittivity and low dissipation factor) and having even further excellent moisture absorption and heat resistance, and even further favorable thermal characteristics, and the insulation layer having an even further favorable peel strength of the metal foil.

The content of thermosetting resin (C) is preferably 60 to 99 parts by mass, more preferably 63 to 98 parts by mass, further preferably 64 to 95 parts by mass, furthermore preferably 65 to 90 parts by mass, and further preferably 70 to 85 parts by mass, based on 100 parts by mass of the total of aromatic phosphorus compound (B) and thermosetting resin (C) in the resin composition, in view of being more compatible with aromatic phosphorus compound (B) and thermosetting resin (C), and in view of a tendency to be able to obtain the cured product having further favorable dielectric characteristics (high permittivity and low dissipation factor) and having further excellent moisture absorption and heat resistance, and further favorable thermal characteristics, and the insulation layer having a further favorable peel strength of the metal foil.

### (Cyanate Ester Compound)

The resin composition of the present embodiment may contain a cyanate ester compound.

For the cyanate ester compound, a known compound can be appropriately used as long as the compound has two or more cyanate groups directly bonding an aromatic ring in the molecule (hereinafter, also referred to as “cyanate ester group”, or “cyanate group”). The cyanate ester compounds can be used singly, or two or more thereof can also be used in combination.

Examples of such a cyanate ester compound include phenol novolac-type cyanate ester compounds, cresol novolac-type cyanate ester compounds, naphthalene ring-containing novolac-type cyanate ester compounds, allyl group-containing novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallylbisphenol A-type cyanate ester compounds, bisphenol E-type cyanate ester compounds, bisphenol F-type cyanate ester compounds, biphenyl aralkyl-type cyanate ester compounds, bis(3,3-dimethyl-4-cyanatephenyl)methane, 1,3-dicyanatebenzene, 1,4-dicyanatebenzene, 1,3,5-tricyanatebenzene, 1,3-dicyanatenaphthalene, 1,4-dicyanatenaphthalene, 1,6-dicyanatenaphthalene, 1,8-dicyanatenaphthalene, 2,6-dicyanatenaphthalene, 2,7-dicyanatenaphthalene, 1,3,6-tricyanatenaphthalene, 4,4′-dicyanatebiphenyl, bis(4-cyanatephenyl)ether, bis(4-cyanatephenyl)thioether, and bis(4-cyanatephenyl)sulfone. These cyanate ester compounds can be made into prepolymers or polymers of cyanate ester compounds.

The cyanate ester compound preferably contains one or more selected from the group consisting of phenol novolac-type cyanate ester compounds, naphthol aralkyl-type cyanate ester compounds, naphthylene ether-type cyanate ester compounds, xylene resin-type cyanate ester compounds, bisphenol M-type cyanate ester compounds, bisphenol A-type cyanate ester compounds, diallylbisphenol A-type cyanate ester compounds, bisphenol E-type cyanate ester compounds, bisphenol F-type cyanate ester compounds, and biphenyl aralkyl-type cyanate ester compounds, and prepolymers or polymers of these cyanate ester compounds, and more preferably contains one or more selected from the group consisting of naphthol aralkyl-type cyanate ester compounds and bisphenol A-type cyanate ester compounds, in view of more dispersing dielectric powder (A) and being more compatible with aromatic phosphorus compound (B), and in view of a tendency to be able to obtain the cured product having more favorable dielectric characteristics (high permittivity and low dissipation factor) and having superior moisture absorption and heat resistance, and more favorable thermal characteristics, and the insulation layer having a more favorable peel strength of the metal foil.

Such a naphthol aralkyl-type cyanate ester compound is more preferably a compound represented by a formula (10).

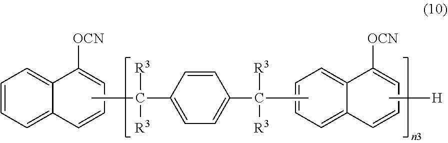

In the formula (10), R³ each independently represents a hydrogen atom or a methyl group, and, in particular, preferably a hydrogen atom. In the formula (1), n3 is an integer of 1 or more, preferably an integer of 1 to 20, and more preferably an integer of 1 to 10.

For the bisphenol A-type cyanate ester compound, one or more selected from the group consisting of 2,2-bis(4-cyanatephenyl)propane and prepolymers of 2,2-bis(4-cyanatephenyl)propane can be used.

Such a bisphenol A-type cyanate ester compound can be a commercial product, and examples include Primaset (registered trademark) BADCy (product name, Lonza K.K., 2,2-bis(4-cyanatephenyl)propane, cyanate ester group equivalent: 139 g/eq.) and CA210 (product name, Mitsubishi Gas Chemical Company, Inc., a prepolymer of 2,2-bis(4-cyanatephenyl)propane, cyanate ester group equivalent: 139 g/eq.).

These cyanate ester compounds can be produced in accordance with a known method. Examples of the specific production method include a method described in Japanese Patent Laid-Open No. 2017-195334 (particularly, paragraphs from 0052 to 0057).

The content of the cyanate ester compound is preferably 1 to 65 parts by mass, more preferably 2 to 60 parts by mass, further preferably 3 to 55 parts by mass, furthermore preferably 4 to 50 parts by mass, further preferably 5 to 45 parts by mass, and still further preferably 6 to 40 parts by mass, based on 100 parts by mass of the total resin solid content in the resin composition. When a content of the cyanate ester compound is within the above range, the dispersibility of dielectric powder (A) and the compatibility with aromatic phosphorus compound (B) are even more favorable, and there is a tendency that it is possible to obtain the cured product having even more favorable dielectric characteristics (high permittivity and low dissipation factor) and having even superior moisture absorption and heat resistance, and even more favorable thermal characteristics, and the insulation layer having even more favorable peel strength of the metal foil.

### (Maleimide Compound)

The resin composition of the present embodiment can contain a maleimide compound.

For the maleimide compound, a known compound can be appropriately used as long as the compound has one or more maleimide groups in a molecule, and the kind thereof is not particularly limited. The number of maleimide groups in a molecule of the maleimide compound is one or more, and preferably two or more. The maleimide compounds can be used singly, or two or more thereof can also be used in combination.

Examples of the maleimide compound include N-phenylmaleimide, N-hydroxyphenylmaleimide, bis(4-maleimidephenyl)methane, 2,2-bis(4-(4-maleimidephenoxy)-phenyl)propane, bis(3,5-dimethyl-4-maleimidephenyl)methane, bis(3-ethyl-5-methyl-4-maleimidephenyl)methane, bis(3,5-diethyl-4-maleimidephenyl)methane, maleimide compounds represented by the formula (11), maleimide compounds represented by the formula (12), and maleimide compounds represented by the formula (13), prepolymers of the above maleimide compounds, and prepolymers of the above maleimide compound and an amine compound.

The maleimide compound is preferably a maleimide compound having an aromatic backbone, more preferably contains one or more selected from the group consisting of bis(4-maleimidephenyl)methane, 2,2-bis(4-(4-maleimidephenoxy)-phenyl)propane, bis(3-ethyl-5-methyl-4-maleimidephenyl)methane, maleimide compounds represented by the formula (11), maleimide compounds represented by the formula (12), and maleimide compounds represented by the formula (13), and further preferably contains one or more selected from the group consisting of bis(3-ethyl-5-methyl-4-maleimidephenyl)methane, maleimide compounds represented by the formula (12), and maleimide compounds represented by the formula (13), in view of more dispersing dielectric powder (A) and being more compatible with aromatic phosphorus compound (B), and in view of a tendency to be able to obtain the cured product having more favorable dielectric characteristics (high permittivity and low dissipation factor) and having superior moisture absorption and heat resistance, and more favorable thermal characteristics, and the insulation layer having a more favorable peel strength of the metal foil. It is further preferable to contain the maleimide compound represented by the formula (13), in view of obtaining a resin composition having an even lower dissipation factor. It is preferable to contain the maleimide compound represented by the formula (12), in view of obtaining the cured product having even superior dielectric characteristics, moisture absorption and heat resistance, and thermal characteristics, and obtaining the insulation layer having an even more favorable peel strength of the metal foil.

In the present embodiments, when the resin composition contains a maleimide compound having an aromatic backbone, there is a tendency that it is possible to obtain the cured product having more favorable dielectric characteristics (high permittivity and low dissipation factor) and having superior moisture absorption and heat resistance, and more favorable thermal characteristics, and the insulation layer having a more favorable peel strength of the metal foil. The reason is not clear but the present inventors infer as follows. Specifically, it is inferred that the above effects are obtained because, when the resin composition contains a maleimide compound having an aromatic backbone, more compatibility with aromatic phosphorus compound (B) and more dispersing of dielectric powder (A) can be achieved. However, the mechanism is not limited to this.

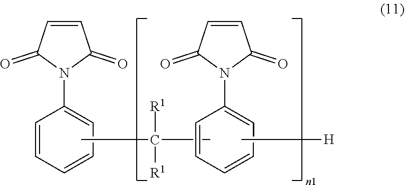

In the formula (11), R¹ each independently represents a hydrogen atom or a methyl group, and n1 is an integer of 1 to 10.

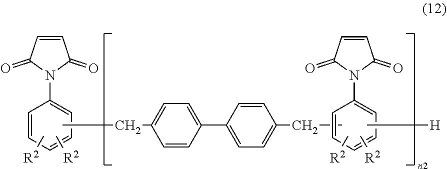

In the formula (12), R² each independently represents a hydrogen atom, an alkyl group having 1 to 5 carbon atoms, or a phenyl group, and n2 is an average value and represents 1<n2≤5.

Examples of the alkyl group having 1 to 5 carbon atoms include straight-chain alkyl groups such as a methyl group, an ethyl group, a propyl group, a butyl group, and a pentyl group; and branched-chain alkyl groups such as an isopropyl group, an isobutyl group, a sec-butyl group, and a tert-butyl group.

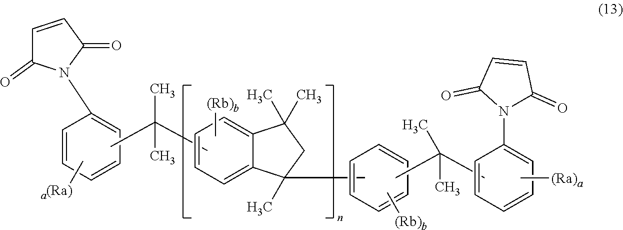

In the formula (13), Ra each independently represents an alkyl group, an alkyloxy group or an alkylthio group having 1 to 10 carbon atoms, an aryl group, an aryloxy group or an arylthio group having 6 to 10 carbon atoms, a cycloalkyl group having 3 to 10 carbon atoms, a halogen atom, a nitro group, a hydroxy group, or a mercapto group; q represents an integer of 0 to 4 and when q is an integer of 2 to 4, Ra can be the same or different in the same ring; Rb each independently represents an alkyl group, an alkyloxy group or an alkylthio group having 1 to 10 carbon atoms, an aryl group, an aryloxy group or an arylthio group having 6 to 10 carbon atoms, a cycloalkyl group having 3 to 10 carbon atoms, a halogen atom, a hydroxy group, or a mercapto group; r represents an integer of 0 to 3, and when r is 2 or 3, Rb can be the same or different in the same ring; and n is the average number of repeating units and represents a value of 0.95 to 10.0.

Examples of the alkyl group having 1 to 10 carbon atoms include, in addition to the above-exemplified alkyl groups having 1 to 5 carbon atoms, a n-pentyl group, an isopentyl group, a neopentyl group, a n-hexyl group, an isohexyl group, a n-heptyl group, a n-octyl group, a 2-ethylhexyl group, a n-nonyl group, an isononyl group, and a n-decyl group.

Examples of the alkyloxy group having 1 to 10 carbon atoms include a methoxy group, an ethoxy group, a n-propoxy group, a n-butoxy group, a n-pentyloxy group, and a n-hexyloxy group.

Examples of the alkylthio group having 1 to 10 carbon atoms include a methylthio group and an ethylthio group.

Examples of the aryl group having 6 to 10 carbon atoms include a phenyl group, a cyclohexylphenyl group, a phenol group, a cyanophenyl group, a nitrophenyl group, a naphthalene group, a biphenyl group, an anthracene group, a naphthacene group, an anthracyl group, a pyrenyl group, a perylene group, a pentacene group, a benzopyrene group, a chrysene group, a pyrene group, and a triphenylene group.

Examples of the aryloxy group having 6 to 10 carbon atoms include a phenoxy group and a p-tolyloxy group.

Examples of the arylthio group having 6 to 10 carbon atoms include a phenylthio group and a p-tolylthio group.

Examples of the cycloalkyl group having 3 to 10 carbon atoms include a cyclopropyl group, a cyclobutyl group, a cyclopentyl group, a cyclohexyl group, and a cycloheptyl group.

Examples of the halogen atom include a fluorine atom, a chlorine atom, a bromine atom, and an iodine atom.

In the formula (13), Ra each independently preferably represents an alkyl group having 1 to 6 carbon atoms, a cycloalkyl group having 3 to 6 carbon atoms, or an aryl group having 6 to 10 carbon atoms.

In the formula (13), q is preferably 2 or 3, and more preferably 2. Herein, other groups than Ra, directly bonding a benzene ring, are a hydrogen atom. Specifically, it is indicated that, for example, when q is 0, all Ra are a hydrogen atom.

In the formula (13), all Rb are preferably a hydrogen atom. It is also preferable that, when r is an integer of 1 to 3, Rb each independently be an alkyl group having 1 to 6 carbon atoms, a cycloalkyl group having 3 to 6 carbon atoms, or an aryl group having 6 to 10 carbon atoms. Herein, other groups than Rb, directly bonding a benzene ring, are a hydrogen atom. Specifically, it is indicated that, for example, when r is 0, all Rb are a hydrogen atom.

The maleimide compound represented by the formula (13) can be produced in accordance with a known method. Examples of the specific production method include a method described in WO 2020/217679.

Maleimide compounds can be a commercial product, or a product produced by a known method can also be used. Examples of the commercial product of the maleimide compound include BMI-70 (bis(3-ethyl-5-methyl-4-maleimidephenyl)methane), BMI-80 (2,2-bis(4-(4-maleimidephenoxy)-phenyl)propane), and BMI-1000P (all product names, K.I Chemical Industry Co., Ltd.); BMI-3000, BMI-4000, BMI-5100, BMI-7000, and BMI-2300 (the maleimide compounds represented by the above formula (11)) (all product names, Daiwa Kasei Industry Co., Ltd.); MIR-3000-70MT (product name, the maleimide compound represented by the above formula (12), Nippon Kayaku Co., Ltd.); and NE-X-9470S (product name, the maleimide compound represented by the above formula (13), DIC corporation).

The content of the maleimide compound is preferably 15 to 85 parts by mass, more preferably 20 to 80 parts by mass, and further preferably 25 to 75 parts by mass, based on 100 parts by mass of the total resin solid content in the resin composition. When a content of the maleimide compound is within the above range, the dispersibility of dielectric powder (A) and the compatibility with aromatic phosphorus compound (B) are even more favorable, and there is a tendency that it is possible to obtain the cured product having even more favorable dielectric characteristics (high permittivity and low dissipation factor) and having even superior moisture absorption and heat resistance, and even more favorable thermal characteristics, and the insulation layer having even more favorable peel strength of the metal foil.

### (Epoxy Compound)

The resin composition of the present embodiment can contain an epoxy compound.

For the epoxy compound, a known compound can be appropriately used as long as the compound has one or more epoxy groups in a molecule, and the kind thereof is not particularly limited. The number of epoxy groups in a molecule of the epoxy compound is one or more, and preferably two or more. The epoxy compounds can be used singly, or two or more thereof can also be used in combination.

For epoxy compound, conventionally known epoxy compounds and epoxy resins can be used. Examples include biphenyl aralkyl-type epoxy resins, naphthalene-type epoxy resins, bisnaphthalene-type epoxy resins, polyfunctional phenol-type epoxy resins, naphthylene ether-type epoxy resins, phenol aralkyl-type epoxy resins, phenol novolac-type epoxy resins, cresol novolac-type epoxy resins, xylene novolac-type epoxy resins, naphthalene backbone-modified novolac-type epoxy resins, dicyclopentadiene novolac-type epoxy resins, biphenyl novolac-type epoxy resins, phenol aralkyl novolac-type epoxy resins, naphthol aralkyl novolac-type epoxy resins, aralkyl novolac-type epoxy resins, aromatic hydrocarbon formaldehyde-type epoxy compounds, anthraquinone-type epoxy compounds, anthracene-type epoxy resins, naphthol aralkyl-type epoxy compounds, dicyclopentadiene-type epoxy resins, ZYLOCK-type epoxy compounds, bisphenol A-type epoxy resins, bisphenol E-type epoxy resins, bisphenol F-type epoxy resins, bisphenol S-type epoxy resins, bisphenol A novolac-type epoxy resins, phenol-type epoxy compounds, biphenyl-type epoxy resins, aralkyl novolac-type epoxy resins, triazine backbone epoxy compounds, triglycidyl isocyanurate, alicyclic epoxy resins, polyol-type epoxy resins, glycidylamine, glycidyl-type ester resins, compounds obtained by epoxidating a double bond of a double bond-containing compound such as butadiene, and compounds obtained by reaction of hydroxy group-containing silicone resins and epichlorohydrin.

The epoxy compound preferably contains one or more selected from the group consisting of biphenyl aralkyl-type epoxy resins, naphthalene-type epoxy resins, naphthylene ether-type epoxy resins, and butadiene backbone-containing epoxy resins, and more preferably contains one or more selected from the group consisting of naphthalene-type epoxy resins and biphenyl aralkyl-type epoxy resins, in view of more dispersing dielectric powder (A) and being more compatible with aromatic phosphorus compound (B), and in view of a tendency to be able to obtain the cured product having more favorable dielectric characteristics (high permittivity and low dissipation factor) and having superior moisture absorption and heat resistance, and more favorable thermal characteristics, and the insulation layer having a more favorable peel strength of the metal foil.

The biphenyl aralkyl-type epoxy resins are preferably compounds represented by the following formula (14).

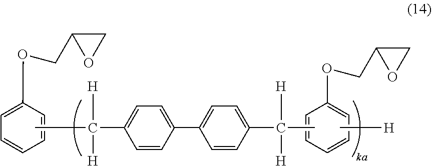

In the formula (14), ka represents an integer of 1 or more, is preferably an integer 1 to 20, and more preferably an integer 1 to 10.

Biphenyl aralkyl-type epoxy resins can be a commercial product, or a product produced by a known method can also be used. Examples of the commercial products include NC-3000, NC-3000L, NC-3000H, and NC-3000FH (the compounds represented by the above formula (14), in the formula (14), ka is an integer of 1 to 10) (all product names, Nippon Kayaku Co., Ltd.).

Naphthalene-type epoxy resins are preferably the compound represented by the following formula (15).

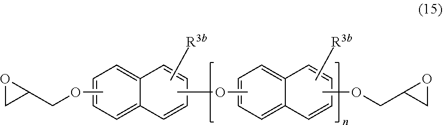

In the formula (15), R^{3b} each independently represents a hydrogen atom, an alkyl group having 1 to 5 carbon atoms (e.g., a methyl group or an ethyl group), an aralkyl group, a benzyl group, a naphthyl group, a naphthyl group containing at least one glycidyloxy group, or a naphthylmethyl group containing at least one glycidyloxy group, and n represents an integer of 0 or more (e.g., 0 to 2).

Examples of the commercial products of the compounds represented by the above formula (15) include “EPICLON (registered trademark) EXA-4032-70M” (in the above formula (3), n=0, and R^{3b} being all hydrogen atoms), and EPICLON (registered trademark) HP-4710 (in the above formula (15), n=0, and R^{3b} is a naphthylmethyl group containing at least one glycidyloxy group) (all product names, DIC corporation).

Naphthylene ether-type epoxy resins are preferably the bifunctional epoxy compound represented by the following formula (16) or the polyfunctional epoxy compound represented by the following formula (17), or a mixture thereof.

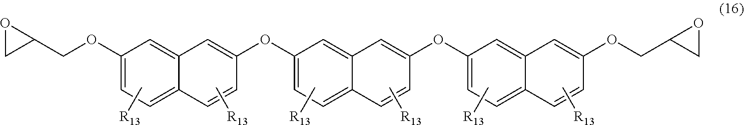

In the formula (16), R₁₃ each independently represents a hydrogen atom, an alkyl group having 1 to 3 carbon atoms (e.g., a methyl group or an ethyl group), or an alkenyl group having 2 to 3 carbon atoms (e.g., a vinyl group, an allyl group, or a propenyl group).

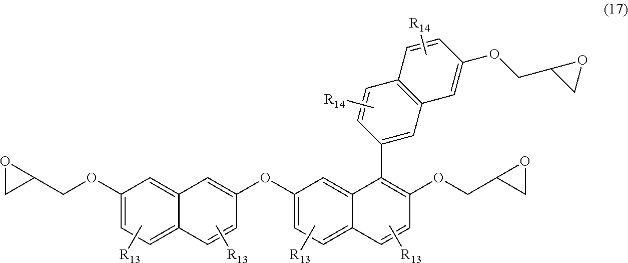

In the formula (17), R₁₄ each independently represents a hydrogen atom, an alkyl group having 1 to 3 carbon atoms (e.g., a methyl group or an ethyl group), or an alkenyl group having 2 to 3 carbon atoms (e.g., a vinyl group, an allyl group, or a propenyl group).

Naphthylene ether-type epoxy resins can be a commercial product, or a product produced by a known method can also be used. Examples of the commercial products include HP-6000, EXA-7300, EXA-7310, EXA-7311, EXA-7311L, EXA7311-G3, EXA7311-G4, EXA-7311G4S, and EXA-7311G5 (all product names, DIC corporation). Of these, HP-6000 (product name) is preferable.

Butadiene backbone-containing epoxy resins can be any epoxy resins as long as the resin has the butadiene backbone and an epoxy group in a molecule. Examples of the resin include the butadiene backbone-containing epoxy resins represented by the following formulae (18) to (20).

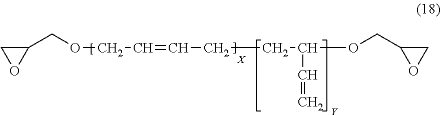

In the formula (18), X represents an integer of 1 to 100, and Y represents an integer of 0 to 100. PGP-48C

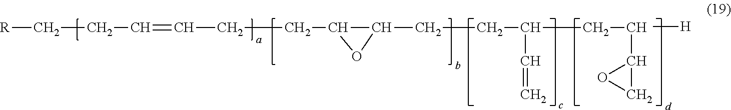

In the formula (19), R represents a hydrogen atom or an alkyl group having 1 to 10 carbon atoms, a and b each independently represent an integer of 1 to 100, c and d each independently represent an integer of 0 to 100. Examples of the alkyl group include a methyl group, an ethyl group, a propyl group, and a butyl group.

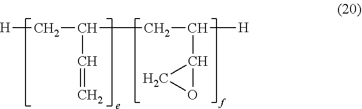

In the formula (20), e represents an integer of 24 to 35, and f represents an integer of 8 to 11.

Butadiene backbone-containing epoxy resins can be a commercial product, or a product produced by a known method can also be used. Examples of the commercial products include R-15EPT and R-45EPT (the compound having, in the above formula (18), X=50 and Y=0) (all product names, Nagase ChemteX Corporation); EPOLEAD (registered trademark) PB3600 and PB4700 (all product names, Daicel Corporation); and Nisseki polybutadiene E-1000-3.5 (product name, Nippon Petrochemicals Co., Ltd.).

The content of the epoxy compound is preferably 1 to 50 parts by mass, more preferably 10 to 45 parts by mass, and further preferably 20 to 40 parts by mass, based on 100 parts by mass of the total resin solid content in the resin composition. When a content of the epoxy compound is within the above range, the dispersibility of dielectric powder (A) and the compatibility with aromatic phosphorus compound (B) are even more favorable, and there is a tendency that it is possible to obtain the cured product having even more favorable dielectric characteristics (high permittivity and low dissipation factor) and having even superior moisture absorption and heat resistance, and even more favorable thermal characteristics, and the insulation layer having even more favorable peel strength of the metal foil.

### (Phenol Compound)

The resin composition of the present embodiment can contain a phenol compound.

For the phenol compound, a known compound can be appropriately used as long as the compound has two or more phenolic hydroxy groups in a molecule, and the kind thereof is not particularly limited. The phenol compounds can be used singly, or two or more thereof can also be used in combination.

Examples of the phenol compound include cresol novolac-type phenolic resins, biphenyl aralkyl-type phenolic resins represented by a formula (21), naphthol aralkyl-type phenolic resins represented by a formula (22), aminotriazine novolac-type phenolic resins, naphthalene-type phenolic resins, phenol novolac resins, alkylphenol novolac resins, bisphenol A-type novolac resins, dicyclopentadiene-type phenolic resins, ZYLOCK-type phenolic resins, terpene-modified phenolic resins, and polyvinylphenols.

Of these, one or more selected from the group consisting of cresol novolac-type phenolic resins, biphenyl aralkyl-type phenolic resins represented by the formula (21), naphthol aralkyl-type phenolic resins represented by the formula (22), aminotriazine novolac-type phenolic resins, and naphthalene-type phenolic resins are preferable, and one or more selected from the group consisting of biphenyl aralkyl-type phenolic resins represented by the formula (21) and naphthol aralkyl-type phenolic resins represented by the formula (22) are more preferable, in view of imparting excellent formability and surface hardness.

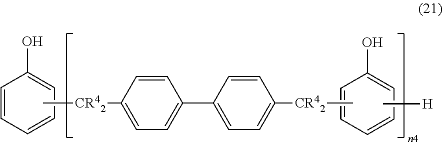

In the formula (21), R⁴ each independently represents a hydrogen atom or a methyl group, n4 is an integer of 1 to 10.

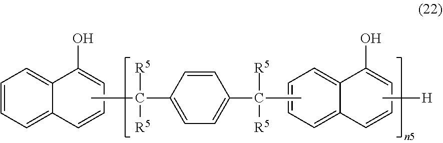

In the formula (22), R⁵ each independently represents a hydrogen atom or a methyl group, and n5 is an integer of 1 to 10.

The content of the phenol compound is preferably 1 to 50 parts by mass, more preferably 5 to 40 parts by mass, and further preferably 10 to 30 parts by mass, based on 100 parts by mass of the total resin solid content in the resin composition. When a content of phenol compound is within the above range, the adhesivity, flexibility and the other properties tend to be superior.

### (Modified Polyphenylene Ether Compound)

The resin composition of the present embodiment can contain a modified polyphenylene ether compound.

For the modified polyphenylene ether compound, a known compound can be appropriately used and is not particularly limited as long as the polyphenylene ether compound is modified at a part or all of the terminals thereof. Herein, the “modified” of the modified polyphenylene ether compound means that the polyphenylene ether compound is substituted at a part or all of the terminals thereof with a reactive functional group such as a carbon-carbon unsaturated double bond. The modified polyphenylene ether compounds can be used singly, or two or more thereof can also be used in combination.

Examples of the polyphenylene ether compound for the modified polyphenylene ether compound include polymers including at least one structural unit selected from the structural units represented by a formula (23), the structural units represented by a formula (24), and the structural units represented by a formula (25).

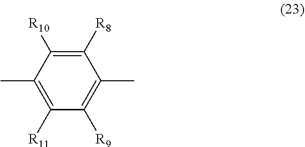

In the formula (23), Re, R₉, R₁₀, and R₁₁ each independently represent an alkyl group having 6 or less carbon atoms, an aryl group, a halogen atom, or a hydrogen atom.

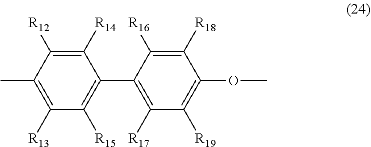

In the formula (24), R₁₂, R₁₃, R₁₄, R₁₈, and R₁₉ each independently represent an alkyl group having 6 or less carbon atoms or a phenyl group. R₁₅, R₁₆, and R₁₇ each independently represent a hydrogen atom, an alkyl group having 6 or less carbon atoms or a phenyl group.

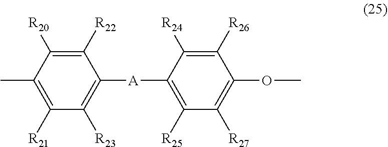

In the formula (25), R₂₀, R₂₁, R₂₂, R₂₃, R₂₄, R₂₅, R₂₆, and R₂₇ each independently represent a hydrogen atom, an alkyl group having 6 or less carbon atoms, or a phenyl group. -A- represents a straight-, branched-, or cyclic-chain divalent hydrocarbon group having 20 or less carbon atoms.

In the formula (25), examples of the -A- include, but not limited to, divalent organic groups such as a methylene group, an ethylidene group, a 1-methylethylidene group, a 1,1-propylidene group, a 1,4-phenylenebis(1-methylethylidene) group, a 1,3-phenylenebis(1-methylethylidene) group, a cyclohexylidene group, a phenylmethylene group, a naphthylmethylene group, and a 1-phenylethylidene group.

The modified polyphenylene ether compound is preferably, for example, modified polyphenylene ether compounds modified by a functional group such as an ethylenically unsaturated group such as a vinyl benzyl group, an epoxy group, an amino group, a hydroxy group, a mercapto group, a carboxy group, a methacryl group, and a silyl group at a part or all of the terminals of a polyphenylene ether compound.

Examples of the modified polyphenylene ether compound whose terminal is a hydroxy group include SA90 (product name, SABIC innovative plastics).

Examples of the modified polyphenylene ether compound whose terminal is a methacryl group include SA9000 (product name, SABIC innovative plastics).

The production method of the modified polyphenylene ether compound is not particularly limited as long as the effects of the present invention can be obtained. For example, the modified polyphenylene ether compound can be produced by the method described in U.S. Pat. No. 4,591,665.

The modified polyphenylene ether compound more preferably contains a modified polyphenylene ether compound having a terminal ethylenically unsaturated group. Examples of the ethylenically unsaturated group include alkenyl groups such as an ethenyl group, an allyl group, an acryl group, a methacryl group, a propenyl group, a butenyl group, a hexenyl group, and an octenyl group; cycloalkenyl groups such as cyclopentenyl group and a cyclohexenyl group; and alkenylaryl groups such as a viny benzyl group and a vinyl naphthyl group. Of these, a vinyl benzyl group is preferable.

The terminal ethylenically unsaturated group can be one or more, and can be the same functional group or different functional groups.

In view of allowing dielectric powder (A) to be more dispersed and allowing for more compatibility with aromatic phosphorus compound (B), and in view of a tendency to be able to obtain the cured product having more favorable dielectric characteristics (high permittivity and low dissipation factor) and having superior moisture absorption and heat resistance, and more favorable thermal characteristics, and the insulation layer having a more favorable peel strength of the metal foil, the modified polyphenylene ether compound having a terminal ethylenically unsaturated group is preferably the compounds represented by a formula (26).

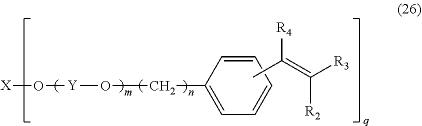

In the formula (26), X represents an aromatic group, and —(Y—O)ₘ— represents a polyphenylene ether moiety. R₁, R₂, and R₃ each independently represent a hydrogen atom, an alkyl group, an alkenyl group, or an alkynyl group, m represents an integer of 1 to 100, n represents an integer of 1 to 6, q represents an integer of 1 to 4. m is preferably an integer of 1 to 50, and more preferably 1 to 30. n is preferably an integer of 1 to 4, more preferably 1 or 2, and ideally 1. q is preferably an integer of 1 to 3, more preferably 1 or 2, and ideally 2.

Examples of the aromatic group represented by X in the formula (26) include groups formed by removing q hydrogen atoms from one ring structure selected from benzene ring structure, biphenyl ring structure, indenyl ring structure, and naphthalene ring structure (e.g., a phenylene group, a biphenylene group, indenylene group, and a naphthylene group). Of these, a biphenylene group is preferable.

The aromatic group represented by X herein can contain, for example, a group formed by bonding aryl groups via an oxygen atom, such as a diphenyl ether group, a group formed by bonding aryl groups via a carbonyl group, such as a benzophenone group, or a group formed by bonding aryl groups via an alkylene group, such as a 2,2-diphenylpropane group.

The aromatic group can be substituted with a general substituent such as an alkyl group (suitably an alkyl group having 1 to 6 carbon atoms, particularly a methyl group), an alkenyl group, an alkynyl group, and a halogen atom. However, the aromatic group is bonded to a polyphenylene ether moiety via an oxygen atom, and accordingly, the limit in the number of general substituents depends on the number of polyphenylene ether moieties.

For the polyphenylene ether moiety in the formula (26), the structural unit represented by the formula (23), the structural unit represented by the formula (24), and the structural unit represented by the formula (25) can be used. Of these, the structural unit represented by the formula (23) is more preferably contained.

The modified polyphenylene ether compound represented by the formula (26) preferably has a number average molecular weight of 500 to 7000. The modified polyphenylene ether compound represented by the formula (26) having a minimum melt viscosity of 50000 Pa·s or less can be used. The modified polyphenylene ether compound represented by the formula (26) more preferably has a number average molecular weight of 1000 to 7000 and a minimum melt viscosity of 50000 Pa·s or less in view of still more dispersing dielectric powder (A) and being still more compatible with aromatic phosphorus compound (B), and in view of a tendency to be able to obtain the cured product having further favorable dielectric characteristics (high permittivity and low dissipation factor) and having further excellent moisture absorption and heat resistance, and further favorable thermal characteristics, and the insulation layer having a further favorable peel strength of the metal foil.

The number average molecular weight is measured in accordance with a common method using gel permeation chromatography. The number average molecular weight is more preferably 1000 to 3000.

The minimum melt viscosity is measured in accordance with a common method using a dynamic mechanical analyzer. The minimum melt viscosity is more preferably 500 to 50000 Pa·s.

Among the compounds represented by the formula (26), the modified polyphenylene ether compound is preferably the compound represented by the following formula (27).

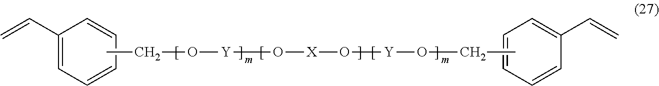

In the formula (27), X is an aromatic group, —(Y—O)ₘ— and —(O—Y)ₘ— each independently represent a polyphenylene ether moiety, and m represents an integer of 1 to 100. m is preferably an integer of 1 to 50, and more preferably an integer of 1 to 30.

X, —(Y—O)ₘ—, and m in the formula (27) are the same as defined for in the formula (26). —(O—Y)ₘ— in the formula (27) is the same as —(Y—O)ₘ— defined in the formula (26).

X in the formula (26) and formula (27) is a formula (28), a formula (29), or a formula (30), and —(Y—O)ₘ— and —(O—Y)ₘ— in the formula (26) and the formula (27) are preferably a structure in which a formula (31) or a formula (32) is arranged, or a structure in which the formula (31) and the formula (32) are arranged in block or randomly.

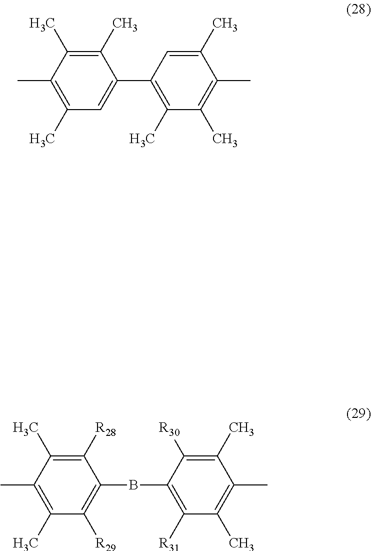

In the formula (29), R₂₆, R₂₉, R₃₀, and R₃₁ each independently represent a hydrogen atom or a methyl group. —B— is a straight-, branched-, or cyclic-chain divalent hydrocarbon group having 20 or less carbon atoms.

Specific examples of —B— include those that are the same as the specific examples of -A- in the formula (25).

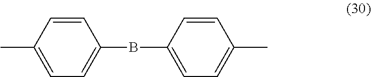

In the formula (30), —B— is a straight-, branched-, or cyclic-chain divalent hydrocarbon group having 20 or less carbon atoms.

Specific examples of —B— include those listed as the specific examples of -A- in the formula (25).

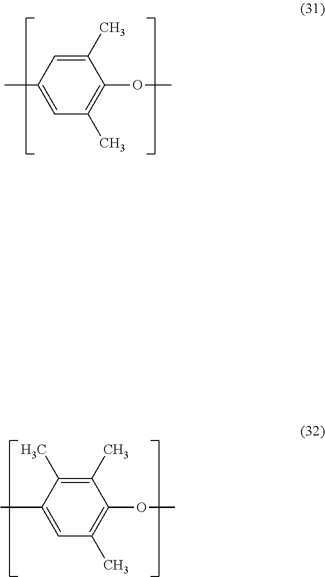

The production method of the modified polyphenylene ether compound having the structure represented by the formula (27) is not particularly limited, and, for example, such a modified polyphenylene ether compound can be produced by oxidatively coupling a bifunctional phenolic compound and a monofunctional phenolic compound to obtain a bifunctional phenylene ether oligomer, and vinylbenzyl-etherifying the terminal phenolic hydroxy group of the obtained bifunctional phenylene ether oligomer.

The modified polyphenylene ether compound can be a commercial product, and, for example, OPE-2St1200, and OPE-2st2200 (all product names, MITSUBISHI GAS CHEMICAL COMPANY, INC.) can be suitably used.

The content of the modified polyphenylene ether compound is preferably 1 to 50 parts by mass, more preferably 5 to 40 parts by mass, and further preferably 10 to 30 parts by mass, based on 100 parts by mass of the total resin solid content in the resin composition. When a content of modified polyphenylene ether compound is within the above range, the low dissipation factor and the reactivity tend to even more enhance.

(Alkenyl-substituted nadiimide Compound)

The resin composition of the present embodiment can contain an alkenyl-substituted nadiimide compounds.

The alkenyl-substituted nadiimide compound is not particularly limited as long as the compound has one or more alkenyl-substituted nadiimide groups in a molecule. The alkenyl-substituted nadiimide compounds can be used singly, or two or more thereof can also be used in combination.

Examples of the alkenyl-substituted nadiimide compound include the compound represented by the following formula (33).

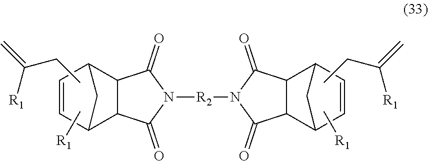

In the formula (33), R₁ each independently represents a hydrogen atom or an alkyl group having 1 to 6 carbon atoms (e.g., a methyl group or an ethyl group), R₂ represents an alkylene group having 1 to 6 carbon atoms, a phenylene group, a biphenylene group, a naphthylene group, or a group represented by a formula (34) or a formula (35).

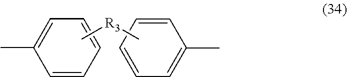

In the formula (34), R₃ represents a methylene group, an isopropylidene group, CO, O, S, or SO₂.

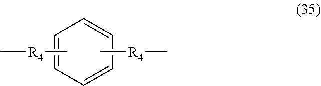

In the formula (35), R₄ each independently represents an alkylene having 1 to 4 carbon atoms, or a cycloalkylene group having 5 to 8 carbon atoms.

The alkenyl-substituted nadiimide compounds represented by the formula (33) can be a commercial product, or a product produced in accordance with a known method can also be used. Examples of the commercial product include BANI-M and BANI-X (all product names, Maruzen Petrochemical Co., Ltd.).

The content of the alkenyl-substituted nadiimide compound is preferably 1 to 50 parts by mass, more preferably 5 to 40 parts by mass, and further preferably 10 to 30 parts by mass, based on 100 parts by mass of the total resin solid content in the resin composition. When a content of the alkenyl-substituted nadiimide compound is within the above range, the adhesivity, flexibility and the other properties tend to be superior.

### (Oxetane Resin)

The resin composition of the present embodiment can contain an oxetane resin.

Oxetane resin is not particularly limited, and a generally known resin can be used. The oxetane resins can be used singly, or two or more thereof can also be used in combination.

Examples of the oxetane resin include alkyloxetane such as oxetane, 2-methyloxetane, 2,2-dimethyloxetane, 3-methyloxetane, and 3,3-dimethyloxetane, 3-methyl-3-methoxymethyloxetane, 3,3-di(trifluoromethyl)perfluorooxetane, 2-chloromethyloxetane, 3,3-bis(chloromethyl)oxetane, biphenyl-type oxetane, OXT-101 (product name, Toagosei Co., Ltd.), and OXT-121 (product name, Toagosei Co., Ltd.).

The content of the oxetane resin is preferably 1 to 50 parts by mass, more preferably 5 to 40 parts by mass, and further preferably 10 to 30 parts by mass, based on 100 parts by mass of the total resin solid content in the resin composition. When a content of the oxetane resin is within the above range, the adhesivity, flexibility and the other properties tend to be superior.

### (Benzoxazine Compound)

The resin composition of the present embodiment can contain a benzoxazine compound.

The benzoxazine compound is not particularly limited as long as the compound has two or more dihydrobenzoxazine rings in a molecule, and a generally known compound can be used. The benzoxazine compounds can be used singly, or two or more thereof can also be used in combination.

Examples of the benzoxazine compound include bisphenol A-type benzoxazine BA-BXZ, bisphenol F-type benzoxazine BF-BXZ, and bisphenol S-type benzoxazine BS-BXZ (all product names, Konishi Chemical Ind. Co., Ltd.).

The content of the benzoxazine compound is preferably 1 to 50 parts by mass, more preferably 5 to 40 parts by mass, and further preferably 10 to 30 parts by mass, based on 100 parts by mass of the total resin solid content in the resin composition. When a content of the benzoxazine compound is within the above range, the adhesivity, flexibility and the other properties tend to be superior.

### (Compound Having a Polymerizable Unsaturated Group)

The resin composition of the present embodiment can contain a compound having a polymerizable unsaturated group.

The compound having a polymerizable unsaturated group is not particularly limited, and a generally known compound can be used. The compounds having a polymerizable unsaturated group can be used singly, or two or more thereof can also be used in combination.

Examples of the compound having a polymerizable unsaturated group include vinyl compounds such as ethylene, propylene, styrene, divinyl benzene, and divinyl biphenyl; meth(acrylates) of monohydric or polyhydric alcohol such as methyl (meth)acrylate, 2-hydroxyethyl (meth)acrylate, 2-hydroxypropyl (meth)acrylate, polypropylene glycol di(meth)acrylate, trimethylolpropane di(meth)acrylate, trimethylolpropane tri(meth)acrylate, pentaerythritol tetra(meth)acrylate, and dipentaerythritol hexa(meth)acrylate; epoxy (meth)acrylates such as bisphenol A-type epoxy (meth)acrylate, and bisphenol F-type epoxy (meth)acrylate; and benzocyclobutene resins.

The content of the compound having a polymerizable unsaturated group is preferably 1 to 50 parts by mass, more preferably 5 to 40 parts by mass, and further preferably 10 to 30 parts by mass, based on 100 parts by mass of the total resin solid content in the resin composition. When a content of the compound having a polymerizable unsaturated group is within the above range, the adhesivity, flexibility and the other properties tend to be superior.

### <Thermoplastic Elastomer>

The resin composition of the present embodiment can contain a thermoplastic elastomer.

The thermoplastic elastomer is not particularly limited as long as it is a thermoplastic elastomer. The thermoplastic elastomers can be used singly, or two or more thereof can also be used in combination.

Examples of the thermoplastic elastomer include styrene-based elastomers, and other thermoplastic elastomers than styrene-based elastomers.

Examples of such a styrene-based elastomer include styrene-butadiene random copolymers, styrene-butadiene-styrene block copolymers, styrene-isoprene-styrene block copolymers, styrene-hydrogenated butadiene-styrene block copolymers, styrene-hydrogenated isoprene-styrene block copolymers, styrene-butadiene block copolymers, styrene-isoprene block copolymers, styrene-hydrogenated butadiene block copolymers, styrene-hydrogenated isoprene block copolymers, and styrene-hydrogenated (isoprene/butadiene) block copolymers.

The styrene (styrene unit) in a polystyrene block structure can have a substituent. Examples of the styrene include α-methylstyrene, 3-methylstyrene, 4-propylstyrene, and 4-cyclohexylstyrene.

The styrene content in the styrene-based elastomer is preferably 10 mass % or more, and more preferably 20 mass % or more in 100 mass % of the styrene-based elastomer. The styrene content is, for example, less than 100 mass %, preferably less than 99 mass %, and more preferably 70 mass % or less in terms of the upper limit. Herein, the styrene content is a value represented by (a)/(b)×100 (unit: mass %) under the assumption that the mass of the styrene unit contained in the styrene-based elastomer is (a) g and the mass of the entire styrene-based elastomer is (b) g.

The styrene-based elastomer can be a commercial product. Examples of the commercial product include TR2630 and TR2003 (all product names, JSR Corporation) as styrene-butadiene-styrene block copolymers; SIS5250 (product name, JSR Corporation) as a styrene-isoprene-styrene block copolymer; SEPTON (registered trademark) 2104 (KURARAY CO., LTD.) as a styrene-hydrogenated isoprene-styrene block copolymer; and H-1043 (product name, Asahi Kasei Corporation) as a styrene-hydrogenated butadiene-styrene block copolymer.

Examples of such other thermoplastic elastomers than styrene-based elastomers include polyisoprene, polybutadiene, butyl rubber, ethylene-propylene rubber, fluorine rubber, silicone rubber, and hydrogenated compounds thereof, and alkyl compounds thereof.

The content of the thermoplastic elastomer is preferably 0.5 to 30 parts by mass, more preferably 1 to 25 parts by mass, further preferably 1.5 to 20 parts by mass, furthermore preferably 2 to 15 parts by mass, and further preferably 3 to 10 parts by mass, based on 100 parts by mass of the total resin solid content in the resin composition. When a content of the thermoplastic elastomer is within the above range, dielectric powder (A) is even more dispersed, even more compatibility with aromatic phosphorus compound (B) and thermosetting resin (C) is achieved, and there is a tendency that it is possible to obtain the cured product having even further favorable dielectric characteristics (high permittivity and low dissipation factor) and having even further excellent moisture absorption and heat resistance, and even further favorable thermal characteristics, and the insulation layer having an even further favorable peel strength of the metal foil.

### <Filler>

The resin composition of the present embodiment can further contain a filler different from dielectric powder (A), in view of more dispersing dielectric powder (A) and in view of a tendency to be able to obtain the cured product having more favorable dielectric characteristics (high permittivity and low dissipation factor) and having superior moisture absorption and heat resistance, and more favorable thermal characteristics, and the insulation layer having a more favorable peel strength of the metal foil. The filler is not particularly limited as long as it is different from dielectric powder (A). The fillers can be used singly, or two or more thereof can also be used in combination.

The relative permittivity of the filler is preferably less than 20, and more preferably 15 or less. In the present embodiment, the relative permittivity of the filler can be measured and calculated by the same method as for dielectric powder (A) described above.

The median particle size (D50) of the filler is preferably 0.10 to 10.0 μm, and more preferably 0.30 to 5.0 μm. The median particle size (D50) of the filler is calculated in the same manner as for the median particle size (D50) of dielectric powder (A) described above.

Examples of the filler include inorganic fillers such as silica, silicon compounds (e.g., white carbon), metal oxides (e.g., alumina, molybdenum compounds (e.g., molybdic acid, zinc molybdates such as ZnMoO₄ and Zn₃Mo₂O₉, ammonium molybdate, sodium molybdate, potassium molybdate, calcium molybdate, molybdenum disulfide, molybdenum trioxide, molybdic acid hydrates, and ammonium zinc molybdate hydrates such as (NH₄)Zn₂Mo₂O₉·(H₃O)), zinc oxide, magnesium oxide, and zirconium oxide), metal nitrides (e.g., boron nitride, silicon nitride, and aluminum nitride), metal sulfates (e.g., barium sulfate), metal hydroxides (e.g., aluminum hydroxide, heated products of aluminum hydroxide (e.g., those obtained by heat treating aluminum hydroxide and reducing a part of water of crystallization), boehmite, and magnesium hydroxide), zinc compounds (e.g., zinc borate and zinc stannate), clay, kaolin, talc, calcined clay, calcined kaolin, mica, E-glass, A-glass, NE-glass, C-glass, L-glass, D-glass, S-glass, M-glass G20, glass short fibers (including glass fine powders such as E glass, T glass, D glass, S glass, and Q glass), hollow glass, spherical glass, and metal microparticles formed by insulating a metal such as gold, silver, palladium, copper, nickel, iron, cobalt, zinc, Mn—Mg—Zn, Ni—Zn, Mn—Zn, carbonyl iron, Fe—Si, Fe—Al—Si, and Fe—Ni; and organic fillers, including powders of rubbers such as styrene-based, butadiene-based, and acryl-based rubbers; core/shell rubber powder; silicone resin powder; silicone rubber powder; and silicone composite powder.

Of these, the filler preferably contains one or more selected from the group consisting of silica, alumina, talc, aluminum nitride, boron nitride, boehmite, aluminum hydroxide, zinc molybdate, silicone rubber powder, and silicone composite powder, and more preferably contains one or more selected from the group consisting of silica, talc, and zinc molybdate.

The filler can be the surface treated filler in which an inorganic oxide is formed on at least a part of the surface of the core particle of the filler. Examples of such a filler include the surface treated molybdenum compound particle (support type) in which an inorganic oxide is formed on at least a part of the surface of core particle made of a molybdenum compound.

The inorganic oxide can be provided on at least a part of the surface of the core particle of the filler. The inorganic oxide can be provided partially on the surface of the core particle of the filler, or can be provided so as to cover the entire surface of the core particle of the filler. The inorganic oxide is uniformly provided so as to cover the entire surface of the core particle of the filler, and specifically, it is preferable that a film of an inorganic oxide be uniformly formed on the surface of the core particle of the filler, in view of obtaining the cured product having more favorable dielectric characteristics (high permittivity and low dissipation factor) and having superior moisture absorption and heat resistance, and more favorable thermal characteristics, and obtaining the insulation layer having a more favorable peel strength of the metal foil.

Examples of the surface treated molybdenum compound particle (supported type) include those obtained by surface treating particles of a molybdenum compound with a silane coupling agent, and those obtained by treating the surface thereof with an inorganic oxide by the sol-gel method, liquid phase deposition method, or the like.

The inorganic oxide is preferably those with excellent heat resistance. The kind thereof is not particularly limited, but a metal oxide is more preferable. Examples of the metal oxide include SiO₂, Al₂O₃, TiO₂, ZnO, In₂O₃, SnO₂, NiO, CoO, V₂O₅, CuO, MgO, and ZrO₂. These can be used singly, or two or more thereof can be appropriately used in combination. Of these, the metal oxide is preferably one or more selected from the group consisting of silica (SiO₂), titanium (TiO₂), alumina (Al₂O₃), and zirconia (ZrO₂), in view of heat resistance, insulation characteristic, and cost, for example.

For the surface treated molybdenum compound particles, it is preferable that the inorganic oxide be provided on at least a part of the surface or the entire surface, and specifically at least on a part or the whole of the outer circumference of the core particle made of the molybdenum compound. Of such surface treated molybdenum compounds particles, it is more preferable that silica as the inorganic oxide is provided on at least a part of the surface or the entire surface, and specifically at least on a part or the whole of the outer circumference of core particles made of the molybdenum compound. The core particle made of the molybdenum compound is more preferably one or more selected from the group consisting of molybdic acid, zinc molybdate, and ammonium zinc molybdate hydrate.

The thickness of the inorganic oxide on the surface can be appropriately set in accordance with desired performances and is not particularly limited. The thickness thereof is preferably 3 to 500 nm, in view of forming a uniform film of the inorganic oxide to provide more favorable close contact with the core particle of the filler, obtaining the cured product having more favorable thermal characteristics, a high glass transition temperature, a low coefficient of thermal expansion, low water absorption, and more favorable dielectric characteristics (high permittivity and low dissipation factor), and obtaining the insulation layer having a more favorable peel strength of the metal foil, and a more suitable surface hardness.

In view of the dispersibility in resin composition, the median particle size (D50) of the surface treated molybdenum compound particles is preferably 0.1 to 10 μm. The median particle size (D50) of the surface treated molybdenum compound particles is calculated in the same manner as for the median particle size (D50) of dielectric powder (A) described above.

The core particle made of the molybdenum compound can be produced by various known methods such as crushing method and granulation method, and the production method thereof is not particularly limited. Additionally, a commercial product thereof can be used.

The production method of the surface treated molybdenum compound particle is not particularly limited, and various know techniques, including the sol-gel method, liquid phase deposition method, dip coating method, spray coating method, printing method, electroless plating method, sputtering method, vapor deposition method, ion plating method, and CVD method, can be appropriately employed to provide the inorganic oxide or a precursor thereof on the surface of the core particle made of the molybdenum compound, whereby the surface treated molybdenum compound particles can be obtained. The method for providing the inorganic oxide or a precursor thereof on the surface of the core particle made of the molybdenum compound can be either a wet method or a dry method.

A preferable example of the production method of the surface treated molybdenum compound particle is as follows: the molybdenum compound (core particles) is dispersed in a solution obtained by dissolving a metal alkoxide such as silicon alkoxide (alkoxysilane) or aluminum alkoxide in an alcohol; a mixed solution of water, alcohol, and a catalyst is added dropwise thereto while stirring to hydrolyze the alkoxide, thereby forming a film of silicon oxide or aluminum oxide as a low refractive index film on the surface of the compound; and then the resulting powder is collected by solid-liquid separation, vacuum dried, and then heat-treated. Another preferable example of the production method is as follows: the molybdenum compound (core particles) is dispersed in a solution obtained by dissolving a metal alkoxide such as silicon alkoxide or aluminum alkoxide in an alcohol; the resultant is mixed at a high temperature and a low pressure, thereby forming a film of silicon oxide or aluminum oxide on the surface of the compound; and then the resulting powder is vacuum dried and crushed. By these methods, the surface treated molybdenum compound particles having a film of a metal oxide such as silica, alumina or the others on the surface of the molybdenum compound can be obtained.

The content of the filler is preferably 50 to 300 parts by mass, based on 100 parts by mass of the total resin solid content in the resin composition. When two or more kinds of fillers are contained, the total amount can be within the above range.

### <Silane Coupling Agent>

The resin composition of the present embodiment can contain a silane coupling agent. When the resin composition contains a silane coupling agent, the dispersibility of dielectric powder (A) and the filler to be blended as needed in the resin composition further enhances, thereby tending to further increase the adhesive strength of each component included in the resin composition to the base material to be described later. The silane coupling agents can be used singly, or two or more thereof can also be used in combination.

The silane coupling agent is not particularly limited, and a silane coupling agent generally used for the surface treatment of an inorganic matter can be used. Examples include aminosilane compounds (e.g., 3-aminopropyltriethoxysilane, and N-β-(aminoethyl)-γ-aminopropyltrimethoxysilane), epoxysilane compounds (e.g., 3-glycidoxy propyltrimethoxysilane), acrylsilane compounds (e.g., γ-acryloxypropyl trimethoxysilane), cationic silane compounds (e.g., N-β-(N-vinylbenzylaminoethyl)-γ-aminopropyltrimethoxysilane hydrochloride), styrylsilane compounds, phenylsilane compounds. The silane coupling agents can be used singly, or two or more thereof can also be used in combination. Of these, the silane coupling agent is preferably one or more selected from the group consisting of epoxysilane compounds and styrylsilane compounds. Examples of the epoxysilane compound include “KBM-403” (product name), “KBM-303” (product name), “KBM-402” (product name), and “KBE-403” (product name) manufactured by Shin-Etsu Chemical Co., Ltd. Examples of the styrylsilane compound include “KBM-1403” (product name).

The content of the silane coupling agent is not particularly limited, and can be 0.1 to 5.0 parts by mass, based on 100 parts by mass of the total resin solid content in the resin composition.

### <Wetting and Dispersing Agent>

The resin composition of the present embodiment can contain a wetting and dispersing agent. When the resin composition contains a wetting and dispersing agent, the dispersibility of the filler tends to be more enhanced. The wetting and dispersing agents can be used singly, or two or more thereof can also be used in combination.

The wetting and dispersing agent can be any known dispersing agent (dispersion stabilizer) used for dispersing the filler, and examples include DISPER BYK (registered trademark)-110, 111, 118, 140, 180, 161, 2009, 2055, 2152, 2155, W969, W996, W9010, W903 (all product names) manufactured by BYK Japan KK.

The content of the wetting and dispersing agent is not particularly limited, and is preferably 0.1 to 10 parts by mass, based on 100 parts by mass of the total resin solid content in the resin composition.

### <Curing Accelerator>

The resin composition of the present embodiment can further contain a curing accelerator. The curing accelerators can be used singly, or two or more thereof can also be used in combination.

Examples of the curing accelerator include imidazoles such as triphenyl imidazole (e.g., 2,4,5-triphenyl imidazole); organic peroxides such as benzoyl peroxide, lauroyl peroxide, acetyl peroxide, para-chlorobenzoyl peroxide, di-tert-butyl-di-perphthalate; azo compounds such as azobisnitrile; tertiary amines such as N,N-dimethylbenzylamine, N,N-dimethylaniline, N,N-dimethyltoluidine, 2-N-ethylanilino ethanol, tri-n-butylamine, pyridine, quinoline, N-methylmorpholine, triethanolamine, triethylenediamine, tetramethylbutanediamine, and N-methyl piperidine; phenols such as phenol, xylenol, cresol, resorcin, and catechol; organic metal salts such as lead naphthenate, lead stearate, zinc naphthenate, zinc octylate, manganese octylate, tin oleate, dibutyltin maleate, manganese naphthenate, cobalt naphthenate, and acetylacetone iron; those obtained by dissolving these organic metal salts in a hydroxy group-containing compound such as phenol and bisphenol; and inorganic metal salts such as stannous chloride, zinc chloride, and aluminum chloride; and organic tin compounds such as dioctyl tin oxide, other alkyl tins. Of these, triphenyl imidazoles such as 2,4,5-triphenyl imidazole and manganese octylate are preferable because these tend to accelerate the curing reaction to increase the glass transition temperature more.

The content of the curing accelerator is not particularly limited, and can be 0.001 parts by mass or more and 2.0 parts by mass or less, or can be 0.01 parts by mass or more and 1.0 parts by mass or less, based on 100 parts by mass of the total resin solid content in the resin composition.

### <Solvent>

The resin composition of the present embodiment can further contain a solvent. When the resin composition contains a solvent, the viscosity of the resin composition when preparing reduces, the handleability (operability) further enhances, and the penetrating ability into a base material tends to further enhance. The solvents can be used singly, or two or more thereof can also be used in combination.

The solvent is not particularly limited as long as it can dissolve a part or all of each of the components in the resin composition. Examples include ketones (acetone, and methyl ethyl ketones), aromatic hydrocarbons (e.g., toluene, and xylene), amides (e.g., dimethyl formaldehyde), propylene glycol monomethyl ether, and acetate thereof.

### <Other Components>

The resin composition of the present embodiment can contain components other than above as long as expected characteristics are not affected. Examples of flame retardant compound include bromine compounds such as 4,4′-dibromobiphenyl; nitrogen-containing compounds such as melamine and benzoguanamine; and silicon compounds. Further, examples of various additives include an ultraviolet absorbent, an antioxidant, a photopolymerization initiator, a fluorescent whitening agent, a photosensitizing agent, a dye, a pigment, a thickener, a lubricant, a defoaming agent, a dispersing agent, a leveling agent (a surface conditioner), a brightening agent, and a polymerization inhibitor.

The content of other components is not particularly limited, and typically 0.01 parts by mass or more and 10 parts by mass or less, respectively, based on 100 parts by mass of the total resin solid content in the resin composition.

### [Production Method of the Resin Composition]

The production method of the resin composition of the present embodiment is, for example, dielectric powder (A), aromatic phosphorus compound (B), thermosetting resin (C), and the components described above, as needed, may be mixed and thoroughly stirred. During this operation, known treatments such as stirring, mixing and kneading can be carried out to homogeneously dissolve or disperse each of the components. Specifically, when the stirring and dispersing treatments are carried out using a stirring tank equipped with a stirrer having a reasonable stirring ability, the dispersibility of dielectric powder (C) and the filler to be blended as needed in the resin composition can be enhanced. The above stirring, mixing, and kneading treatments can be appropriately carried out, for example, by using known devices such as a device for the purpose of mixing such as a ball mill, and a bead mill, or a rotation- or revolution-type mixing device.

During the preparation of the resin composition, a solvent is used as needed, so that the resin composition can be prepared in the form of a resin varnish. The resin varnish can be produced by a known method. The resin varnish can be obtained by, for example, adding 10 to 900 parts by mass of an organic solvent to 100 parts by mass of the components excluding the organic solvent in the resin composition, and carrying out the above known treatments (stirring, mixing, and kneading treatments). The kind of the solvent is not particularly limited as long as it can dissolve the resin in the resin composition. Specific examples thereof are as described above.

### [Usage]

The resin composition of the present embodiment can be suitably used as a material for, for example, a cured product, a prepreg, a film-like underfill material, a resin sheet, a laminate, a build-up material, a non-conductive film, a metal foil-clad laminate, a printed wiring board, and a fiber-reinforced composite material, or for producing a semiconductor device. Hereinafter, these will be described.

### [Cured Product]

The cured product is obtained by curing the resin composition of the present embodiment. In the production method of the cured product, for example, the resin composition of the present embodiment is fused or dissolved in a solvent, then poured into a mold and cured under typical conditions using heat, light or the like to obtain the cured product. In the case of thermosetting, the curing temperature is preferably in a range from 120 to 300° C., in view of efficiently proceeding the curing and preventing the deterioration of a cured product to be obtained.

### [Prepreg]

The prepreg of the present embodiment contains a base material and the resin composition of the present embodiment penetrating or coating the base material. The prepreg of the present embodiment can be obtained by, for example, allowing the resin composition of the present embodiment (e.g., uncured state (stage A)) to penetrate or coat a base material, and then drying at 120 to 220° C. for about 2 to 15 minutes to semi-cure (stage B). In this case, the amount of the resin composition (including the cured product of the resin composition) adhered to the base material, that is, the amount of the resin composition relative to the total amount of the semi-cured prepreg (including the conductive powder (A) and the filler to be blended as needed), is preferably in a range from 20 to 99 mass %. The semi-cured state (stage B) refers that each of the components included in the resin composition has not proactively started reacting (curing) while the resin composition is in a dried state, in other words, the resin composition has been heated to the extent that it is no longer viscous in order to volatilize the solvent, and the semi-cured state encompasses a state in which the resin composition is not cured while the solvent has been simply volatilized even without heating. In the present embodiment, the minimum melt viscosity of the semi-cured state (stage B) is typically 20,000 Pa·s or less. The minimum melt viscosity is, for example, 10 Pa·s or more in terms of the lower limit. In the present embodiment, the minimum melt viscosity is measured by the following method. Specifically, 1 g of a resin powder collected from the resin composition is used as a sample, and a minimum melt viscosity is measured by a rheometer (ARES-G2 (product name), TA Instruments). The minimum melt viscosity of the resin powder herein is measured using a disposable plate having a plate diameter of 25 mm in a range from 40° C. or more and 180° C. or less, under the conditions of a heating rate of 2° C./min, a frequency of 10.0 rad/sec, and a strain of 0.1%.

The base material is not particularly limited as long as it is a base material used for various printed wiring board materials. Examples of the kind of material of the base material include glass fibers (e.g., E-glass, D-glass, L-glass, S-glass, T-glass, Q-glass, UN-glass, and NE-glass), inorganic fibers other than the glass fibers (e.g., quartz), and organic fibers (e.g., polyimide, polyamide, polyester, liquid crystalline polyester, and polytetrafluoroethylene). The form of the base material is not particularly limited, and examples include woven fabrics, unwoven fabrics, rovings, chopped strand mats, and surfacing mats. These base materials can be used singly, or two or more thereof can also be used in combination. Of these base materials, woven fabrics subjected to super fiber opening treatment and filling treatment are preferable in view of the dimensional stability, and glass woven fabrics surface treated with a silane coupling agent such as epoxysilane treatment and aminosilane treatment are preferable, in view of moisture absorption and heat resistance. In view of having excellent dielectric characteristic, glass fibers such as E-glass, L-glass, NE-glass, and Q-glass are preferable.

### [Resin Sheet]

The resin sheet of the present embodiment contains the resin composition of the present embodiment. The resin sheet can also be a resin sheet with a support, which contains a support and a layer formed of the resin composition of the present embodiment disposed on the surface of the support. The resin sheet can be used as a build-up film or dry film solder resist. The production method of the resin sheet is not particularly limited, and examples include a method in which a solution of the resin composition of the present embodiment dissolved in a solvent is applied to (coating) the support and dried to obtain the resin sheet.

Examples of the support include, but not limited to, polyethylene films, polypropylene films, polycarbonate films, polyethylene terephthalate films, ethylene tetrafluoroethylene copolymer films, and mold releasing films obtained by coating the surface of any of these films with a mold release agent, organic film base materials such as polyimide films, conductive foils such as copper foil, and aluminum foil, and plate-like supports such as glass plates, SUS plates, and FRP.

Examples of the coating method (applying method) include a method in which a solution of the resin composition of the present embodiment dissolved in a solvent is applied to the support using a bar coater, a die coater, a doctor blade, or a baker applicator. After drying, the support can be released or etched from the resin sheet with the support, in which the support and the resin composition are laminated, to obtain a single layer sheet (resin sheet). For example, the solution of the resin composition of the present embodiment dissolved in a solvent is fed into a mold having a sheet-like cavity and dried to form a sheet-like shape, thereby to obtain a single layer sheet (resin sheet) without using a support.

In the manufacture of the single layer sheet or the resin sheet with the support according to the present embodiment, the drying conditions for removing the solvent are not particularly limited, but the drying is preferably carried out for 1 to 90 minutes at a temperature of 20 to 200° C., in view of easily removing the solvent in the resin composition and inhibiting the progress of curing while drying. In the single layer sheet or the resin sheet with the support, the resin composition can be used in an uncured state after simply drying the solvent, or can be used in a semi-cured state (stage B) as needed. Further, the thickness of the resin layer of the single layer sheet or the resin sheet with the support according to the present embodiment can be adjusted by the concentration and the coating thickness of the solution of the resin composition of the present embodiment, and not particularly limited, and the thickness is preferably, 0.1 to 500 m in view of easily removing the solvent when drying.

### [Laminate]

The laminate of the present embodiment contains one or more selected from the group consisting of the prepreg and the resin sheet of the present embodiment. In the case of two or more of the prepregs and the resin sheets are laminated, the resin composition used for each prepreg and resin sheet can be the same or different. In the case of using both prepreg and resin sheet, the resin composition used for these can be the same or different. In the laminate of the present embodiment, the one or more selected from the group consisting of the prepreg and the resin sheet can be in a semi-cured state (stage B) or a completely cured state (stage C).

### [Metal Foil-Clad Laminate]

The metal foil-clad laminate of the present embodiment contains the laminate of the present embodiment and a metal foil disposed on one side or each of both sides of the laminate.

The metal foil-clad laminate can contain at least 1 sheet of the prepreg of the present embodiment and a metal foil laminated on one side or each of both sides of the prepreg.

The metal foil-clad laminate can contain at least 1 resin sheet of the present embodiment and a metal foil laminated on one side or each of both sides of the resin sheet.

In the metal foil-clad laminate of the present embodiment, the resin composition used for each prepreg and resin sheet can be the same or different. In the case of using both prepreg and resin sheet, the resin composition used for these can be the same or different. In the metal foil-clad laminate of the present embodiment, the one or more selected from the group consisting of the prepreg and the resin sheet can be in a semi-cured state or a completely cured state.

In the metal foil-clad laminate of the present embodiment, a metal foil is laminated on one or more selected from the group consisting of the prepreg of the present embodiment and the resin sheet of the present embodiment; however, it is preferable that a metal foil be laminated in such a way as to contact the surface of the one or more selected from the group consisting of the prepreg of the present embodiment and the resin sheet of the present embodiment. “The metal foil be laminated in such a way as to contact the surface of the one or more selected from the group consisting of the prepreg and the resin sheet” means that a layer such as an adhesive layer is not included between the prepreg or resin sheet and the metal foil, but that the prepreg or resin sheet directly contacts the metal foil. Due to this, the peel strength of the metal foil of the metal foil-clad laminate increases, and the insulation reliability of a printed wiring board tends to be enhanced.

The metal foil-clad laminate of the present embodiment can have one or more stacked prepregs and/or resin sheets of the present embodiment and the metal foil(s) disposed on one side or both sides of the prepregs and/or resin sheets. Examples of the production method of the metal foil-clad laminate of the present embodiment include a method in which one or more stacked prepregs and/or resin sheets of the present embodiment, and the metal foil(s) disposed on one side or both sides thereof are laminated. Examples of the formation method include a method typically used when forming a laminate and a multilayer board for a printed wiring board, and more specific examples include a method of laminating using a multistage press machine, a multistage vacuum press machine, a continuous molding machine, or an autoclave molding machine, at a temperature of about 180 to 350° C., for heating time of about 100 to 300 minutes, and a surface pressure of about 20 to 100 kgf/cm².

Further, the prepreg and/or the resin sheet of the present embodiment is laminated in combination with a separately manufactured wiring board for an inner layer to form a multilayer board. In the production method of the multilayer board, for example, copper foils having a thickness of about 35 μm are disposed on both sides of one or more stacked prepregs and/or resin sheets of the present embodiment, and laminated by the above formation method to prepare a copper foil-clad laminate. Then, an inner layer circuit is formed and subjected to blacking treatment to form an inner layer circuit board, and then the inner layer circuit boards and the prepregs and/or resin sheets of the present embodiment are alternately disposed one by one. Further, copper foils are disposed on the outermost layers to laminate under the above conditions, preferably under vacuum, whereby a multilayer board can be manufactured. The metal foil-clad laminate of the present embodiment can be suitably used as a printed wiring board.

### (Metal Foil)

The metal foil is not particularly limited, and examples include a gold foil, a silver foil, a copper foil, a tin foil, a nickel foil, and an aluminum foil. Of these, a copper foil is preferable. The copper foil is not particularly limited as long as it is generally used as a material for a printed wiring board, and examples include copper foils such as a rolled copper foil, and an electrolytic copper foil. Of these, an electrolytic copper foil is preferable, in view of copper foil peel strength and fine wiring formation. The thickness of a copper foil is not particularly limited and can be about 1.5 to 70 μm.

### [Printed Wiring Board]

The printed wiring board of the present embodiment has an insulation layer and a conductor layer disposed on one side or each of both sides of the insulation layer, wherein the insulation layer contains a cured product of the resin composition of the present embodiment. The insulation layer preferably contains at least one of a layer formed of the resin composition of the present embodiment (the layer containing the cured product) and a layer formed of the prepreg (the layer containing the cured product). Such a printed wiring board can be produced according to a usual method, and the production method thereof is not particularly limited. For example, the printed wiring board can be produced by using the metal foil-clad laminate described above. Hereinafter, an example of the production method of the printed wiring board is described.

First, the metal foil-clad laminate described above is provided. Next, the surface of the metal foil-clad laminate is subjected to etching treatment to form an inner layer circuit, thereby manufacturing an inner layer substrate. The surface treatment for increasing the adhesive strength is carried out, as needed, on the inner layer circuit surface of this inner layer substrate, then the required number of sheets of the above prepregs are stacked on the inner layer circuit surface, further a metal foil for an outer layer circuit is stacked on the outside thereof, thereby integrating by heating and pressing. Thus, the multilayer laminate is produced in which the base material and the insulation layer consisting of the cured product of the resin composition of the present embodiment are formed between the inner layer circuit and the metal foil for the outer layer circuit. Subsequently, this multilayer laminate is subjected to drilling for a through-hole or a via hole, then a plated metal film is formed on the wall surface of this hole for conducting the inner layer circuit and the metal foil for the outer layer circuit, further the metal foil for the outer layer circuit is subjected to etching treatment to form the outer layer circuit, whereby the printed wiring board is produced.

The printed wiring board obtained in the above production example has the structure in which the insulation layer and the conductor layer formed on the surface of this insulation layer, wherein the insulation layer contains the cured product of the resin composition according to the present embodiment. That is, the prepreg according to the present embodiment (containing the base material and the cured product of the resin composition of the present embodiment penetrating or coating it) and the layer of the resin composition of the metal foil-clad laminate of the present embodiment (the layer containing the cured product of the resin composition of the present embodiment) are structured by the insulation layer containing the cured product of the resin composition of the present embodiment.

### [Semiconductor Device]

The semiconductor device can be produced by mounting a semiconductor tip at a conductive point on the printed wiring board of the present embodiment. The conductive point herein refers to the point at which an electrical signal is transmitted in the multilayer printed wiring board, and such a place can be either on the surface or in an embedded point. Further, the semiconductor tip is not particularly limited as long as it is an electrical circuit element made of a semiconductor as a material.

The method for mounting a semiconductor tip when producing the semiconductor device is not particularly limited as long as the semiconductor tip effectively functions, and specifically examples include wire-bonding mounting method, flip-chip mounting method, bumpless build-up layer (BBUL) mounting method, anisotropic conductive film (ACE) mounting method, and non-conductive film (NCF) mounting method.

### EXAMPLES

Hereinafter, the present embodiment will be more specifically described by way of examples and comparative examples. The present embodiment is not limited at all by the following examples.

### [Measurement Method of Relative Permittivity (Dk) and Dissipation Factor (Df)]

The relative permittivity (Dk) and the dissipation factor (Df) of the dielectric powder (strontium titanate) were measured by the cavity resonator method in the following manner.

First, 200 mg of a dielectric powder was packed in a PTFE (polytetrafluoroethylene) tube (inner diameter: 1.5 mm, manufactured by NICHIAS Corporation), thereby obtaining a sample for measurement (S). On this sample for measurement (S), the relative permittivity (Dk) and dissipation factor (Df) at 10 GHz were measured using a network analyzer (Agilent 8722ES (product name), manufactured by Agilent Technologies, Inc.). The measurement of the relative permittivity (Dk) and dissipation factor (Df) was carried out under the environment at a temperature of 23° C.±1° C., and a humidity of 50% RH (relative humidity)±5% RH. Similarly, a PTFE (polytetrafluoroethylene) tube (inner diameter: 1.5 mm, manufactured by NICHIAS Corporation) itself was used as a blank sample (B), and the relative permittivity (Dk) and the dissipation factor (Df) of this sample (B) at 10 GHz were measured.

From these measurement results, using the following Bruggeman formula (ii), the relative permittivity (Dk) and the dissipation factor (Df) of the dielectric powder at 10 GHz were each calculated.

$${f}_{a} \times [ ( {ε}_{a} - {ε}_{d} ) / ( {ε}_{a} + 2 {ε}_{d} ) ] + {f}_{b} \times [ ( {ε}_{b} - {ε}_{d} ) / ( {ε}_{b} + 2 {ε}_{d} ) ] + {f}_{c} \times [ ( {ε}_{c} - {ε}_{d} ) / ( {ε}_{c} + 2 {ε}_{d} ) ] = 0 \qquad Formula ( ii )$$

In the formula (ii), fₐ is the volume fraction (vol %) of PTFE in the sample for measurement, f_{b} is the volume fraction (vol %) of the air in the sample for measurement, fc is the volume fraction (vol %) of the dielectric powder in the sample for measurement, εₐ is the complex permittivity of PTFE, ε_{b} is the complex permittivity of the air, ε_{c} is the complex permittivity of the dielectric powder, and ε_{d} is the complex permittivity of the sample for measurement.

Specifically, first, in the sample (B), the volume fraction f_{bB} of the air was assumed to be 46 (vol %), and the volume fraction f_{aB} of PTFE was assumed to be 54 (vol %). The complex permittivity is represented by the real part and the imaginary part as “ε=ε′−iε″”. Dk is represented by ε′, and Df is represented by ε″/ε′. Accordingly, the complex permittivity ε_{dB} of the sample (B) (including PTFE and air) was calculated from the measurement results of the sample (B) (Dk and Df). Next, the complex permittivity of the air ε_{bB} is 1.0 when the real part and the imaginary part are assumed to be 1.0 and 0, respectively, and thus, the complex permittivity of PTFE Ea was calculated by assigning f_{aB}, f_{bB}, ε_{dB}, and ε_{bB} to the formula (ii).

Then, for the sample for measurement (S) (including PTFE, air, and dielectric powder), the volume fraction f_{cS} (vol %) of the dielectric powder was calculated from the inner diameter and the length of the PTFE tube, the mass difference between before and after packing the dielectric powder, and the specific gravity of the dielectric powder. On the assumption that the volume fraction f_{aS} of PTFE is 54 (vol %), the volume fraction f_{bS} (vol %) of the air was calculated from the found volume fraction f_{cS}. Next, in the same manner as for the sample (B), the complex permittivity of the sample (S) ε_{d}s (including PTFE, air, and dielectric powder) was calculated from the measurement results (Dk and Df) of the sample for measurement (S). On the assumption that the complex permittivity of the air ε_{b} is 1.0, the complex permittivity of the dielectric powder ε_{c} was calculated by the formula (ii) from La calculated for the sample (B) and f_{aS}, f_{bS}, f_{cS}, and ε_{dS}. Dk and Df of the dielectric powder were calculated from the calculated ε_{c}.

### [Measurement Method of Median Particle Size]

The median particle size (D50) of the dielectric powder (strontium titanate) was calculated by measuring a particle size distribution by the laser diffraction scattering method under the following measurement conditions using a laser diffraction scattering type particle size distribution analyzer (Microtrac (registered trademark) MT3300EXII (product name), MicrotracBEL Corp.).

### (Conditions for Measurement Using a Laser Diffraction-Scattering Type Particle Size Distribution Analyzer)

### (Strontium Titanate)

Solvent: methyl ethyl ketone, solvent refractive
index: 1.33, particle refractive index: 2.41,
transmittance: 85±5%.

### [Synthesis Example 1] Synthesis of 1-naphthol aralkyl-type cyanate ester compound (SN495V-CN)

300 g of 1-naphthol aralkyl-type phenolic resin (in terms of OH group 1.28 mol) (SN495V (product name), OH group (hydroxy group) equivalent: 236 g/eq., new Nippon Steel Chemical Co., Ltd.) and 194.6 g of triethylamine (1.92 mol) (1.5 mol based on 1 mol of hydroxy group) were dissolved in 1800 g of dichloromethane, and the resultant was designated as Solution 1. 125.9 g of cyanogen chloride (2.05 mol) (1.6 mol based on 1 mol of hydroxy group), 293.8 g of dichloromethane, 194.5 g of 36% hydrochloric acid (1.92 mol) (1.5 mol based on 1 mol of hydroxy group), and 1205.9 g of water were stirred while maintaining the solution temperature at −2 to −0.5° C., into which Solution 1 was pored over a period of 30 minutes. After completion of pouring Solution 1, the resulting solution was stirred at the same temperature for 30 minutes, and a solution in which 65 g of triethylamine (0.64 mol) (0.5 mol based on 1 mol of hydroxy group) was dissolved in 65 g of dichloromethane (Solution 2) was poured thereinto over a period of 10 minutes. After completion of pouring Solution 2, the resultant was stirred for 30 minutes at the same temperature, and the reaction was completed. Subsequently, the reaction liquid was allowed to stand for separating the organic phase and the aqueous phase, and the obtained organic phase was washed 5 times with 1300 g of water. An electrical conductivity of waste water at the 5th water-washing was 5 μS/cm, thereby confirming that ionic compounds removable by washing with water were sufficiently removed. The organic phase after washed with water was concentrated under reduced pressure and finally concentrated to dryness at 90° C. for 1 hour, thereby obtaining 331 g of the intended 1-naphthol aralkyl-type cyanate ester compound (SN495V-CN, cyanate ester group equivalent: 261 g/eq., R³ in the above formula (10) are all hydrogen atoms, and n3 is an integer of 1 to 10) (orange color viscous substance). An infrared absorption spectrum of the obtained SN495V-CN showed the absorption at 2250 cm-1 (cyanate ester group), and did not show the absorption of hydroxy group.

### Example 1

A resin varnish was obtained by mixing 25 parts by mass of the 1-naphthol aralkyl-type cyanate ester compound (SN495V-CN) obtained in Synthesis Example 1, 30 parts by mass of a biphenyl aralkyl-type maleimide compound (MIR-3000-70MT (product name), Nippon Kayaku Co., Ltd.), 10 parts by mass of bis(3-ethyl-5-methyl-4-maleimidephenyl)methane (BMI-70 (product name), K.I Chemical Industry Co., Ltd.), 20 parts by mass of a biphenyl aralkyl-type epoxy resin (NC-3000FH (product name), epoxy equivalent: 328 g/eq., manufactured by Nippon Kayaku Co., Ltd.), 5 parts by mass of a naphthalene-type epoxy resin (EPICLON (registered trademark) EXA-4032-70M (product name), epoxy equivalent: 150 g/eq., manufactured by DIC corporation), 10 parts by mass of 1,3-phenylenebis(2,6-dixylenyl phosphate) (PX-200 (product name), Daihachi Chemical Industry Co., Ltd.), 300 parts by mass of strontium titanate (SrTiO₃, an oxide of Perovskite structure, median particle size (D50): 0.3 μm, relative permittivity (Dk): 21, dissipation factor (Df): 0.007, ST-03 (product name), manufactured by SAKAI CHEMICAL INDUSTRY CO., LTD.), 3 parts by mass of a wetting and dispersing agent (BYK (registered trademark)-W903 (product name), manufactured by BYK Japan KK), 0.1 parts by mass of 2,4,5-triphenyl imidazole (manufactured by Tokyo Chemical Industry Co., Ltd.), 0.5 parts by mass of manganese octylate (Nikka Octhix Manganese (product name), manufactured by Nihon Kagaku Sangyo Co., Ltd.), and 100 parts by mass of methyl ethyl ketone.

The obtained resin varnish was allowed to penetrate and coat an E glass cloth (1031NT S640 (product name), manufactured by Arisawa Mfg. Co., Ltd.) having a thickness of 0.094 mm and heated to dry at 130° C. for 3 minutes, thereby obtaining a prepreg having a thickness of 0.1 mm.

Next, electrolytic copper foils (3EC-M3-VLP (product name), manufactured by MITSUI MINING & SMELTING CO., LTD.) having a thickness of 12 μm were disposed on the upper and lower sides of the obtained prepreg, and laminated by vacuum pressing at a surface pressure of 30 kgf/cm² and a temperature of 220° C. for 120 minutes, thereby manufacturing a metal foil-clad laminate (a double-sided copper-clad laminated sheet) having a thickness of 0.124 mm. Physical properties of the obtained prepreg, and metal foil-clad laminate were measured in accordance with the evaluation methods, and the measurement results were shown in Table 1.

### Example 2

A resin varnish was obtained in the same manner as in Example 1, except that 25 parts by mass of a biphenyl aralkyl-type maleimide compound (MIR-3000-70MT (product name)) was used instead of 30 parts by mass of the biphenyl aralkyl-type maleimide compound and 15 parts by mass of 1,3-phenylenebis(2,6-dixylenyl phosphate) (PX-200 (product name), Daihachi Chemical Industry Co., Ltd.) was used instead of 10 parts by mass of the 1,3-phenylenebis(2,6-dixylenyl phosphate).

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Comparative Example 1

A resin varnish was obtained by mixing 25 parts by mass of the 1-naphthol aralkyl-type cyanate ester compound (SN495V-CN) obtained in Synthesis Example 1, 40 parts by mass of a biphenyl aralkyl-type maleimide compound (MIR-3000-70MT (product name), Nippon Kayaku Co., Ltd.), 10 parts by mass of bis(3-ethyl-5-methyl-4-maleimidephenyl)methane (BMI-70 (product name), K.I Chemical Industry Co., Ltd.), 20 parts by mass of a biphenyl aralkyl-type epoxy resin (NC-3000FH (product name), epoxy equivalent: 328 g/eq., manufactured by Nippon Kayaku Co., Ltd.), 5 parts by mass of a naphthalene-type epoxy resin (EPICLON (registered trademark) EXA-4032-70M (product name), epoxy equivalent: 150 g/eq., manufactured by DIC corporation), 300 parts by mass of strontium titanate (SrTiO₃, an oxide of Perovskite structure, median particle size (D50): 0.3 μm, relative permittivity (Dk): 21, dissipation factor (Df): 0.007, ST-03 (product name), manufactured by SAKAI CHEMICAL INDUSTRY CO., LTD.), 3 parts by mass of a wetting and dispersing agent (BYK (registered trademark)-W903 (product name), manufactured by BYK Japan KK), 0.1 parts by mass of 2,4,5-triphenyl imidazole (manufactured by Tokyo Chemical Industry Co., Ltd.), 0.5 parts by mass of manganese octylate (Nikka Octhix Manganese (product name), manufactured by Nihon Kagaku Sangyo Co., Ltd.), and 100 parts by mass of methyl ethyl ketone.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 3

A resin varnish was obtained by mixing 30 parts by mass of the 1-naphthol aralkyl-type cyanate ester compound (SN495V-CN) obtained in Synthesis Example 1, 35 parts by mass of a biphenyl aralkyl-type maleimide compound (MIR-3000-70MT (product name), Nippon Kayaku Co., Ltd.), 15 parts by mass of an indane-type maleimide compound (NE-X-9470S (product name), DIC corporation), 20 parts by mass of 1,3-phenylenebis(2,6-dixylenyl phosphate) (PX-200 (product name), Daihachi Chemical Industry Co., Ltd.), 300 parts by mass of strontium titanate (SrTiO₃, an oxide of Perovskite structure, median particle size (D50): 0.3 μm, relative permittivity (Dk): 21, dissipation factor (Df): 0.007, ST-03 (product name), manufactured by SAKAI CHEMICAL INDUSTRY CO., LTD.), 3 parts by mass of a wetting and dispersing agent (BYK (registered trademark)-W903 (product name), manufactured by BYK Japan KK), 0.1 parts by mass of 2,4,5-triphenyl imidazole (manufactured by Tokyo Chemical Industry Co., Ltd.), 0.5 parts by mass of manganese octylate (Nikka Octhix Manganese (product name), manufactured by Nihon Kagaku Sangyo Co., Ltd.), and 100 parts by mass of methyl ethyl ketone.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 4

A resin varnish was obtained in the same manner as in Example 3, except that 45 parts by mass of the 1-naphthol aralkyl-type cyanate ester compound (SN495V-CN) obtained in Synthesis Example 1 was used instead of 30 parts by mass of the 1-naphthol aralkyl-type cyanate ester compound, 25 parts by mass of a biphenyl aralkyl-type maleimide compound (MIR-3000-70MT (product name)) was used instead of 35 parts by mass of the biphenyl aralkyl-type maleimide compound, and 10 parts by mass of an indane-type maleimide compound (NE-X-9470S (product name)) was used instead of 15 parts by mass of the indane-type maleimide compound.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 5

A resin varnish was obtained by mixing 45 parts by mass of the 1-naphthol aralkyl-type cyanate ester compound (SN495V-CN) obtained in Synthesis Example 1, 50 parts by mass of a biphenyl aralkyl-type maleimide compound (MIR-3000-70MT (product name), Nippon Kayaku Co., Ltd.), 5 parts by mass of 1,3-phenylenebis(2,6-dixylenyl phosphate) (PX-200 (product name), Daihachi Chemical Industry Co., Ltd.), 300 parts by mass of strontium titanate (SrTiO₃, an oxide of Perovskite structure, median particle size (D50): 0.3 μm, relative permittivity (Dk): 21, dissipation factor (Df): 0.007, ST-03 (product name), manufactured by SAKAI CHEMICAL INDUSTRY CO., LTD.), 3 parts by mass of a wetting and dispersing agent (BYK (registered trademark)-W903 (product name), manufactured by BYK Japan KK), 0.1 parts by mass of 2,4,5-triphenyl imidazole (manufactured by Tokyo Chemical Industry Co., Ltd.), 0.5 parts by mass of manganese octylate (Nikka Octhix Manganese (product name), manufactured by Nihon Kagaku Sangyo Co., Ltd.), and 100 parts by mass of methyl ethyl ketone.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Comparative Example 2

A resin varnish was obtained by mixing 40 parts by mass of the 1-naphthol aralkyl-type cyanate ester compound (SN495V-CN) obtained in Synthesis Example 1, 40 parts by mass of a biphenyl aralkyl-type maleimide compound (MIR-3000-70MT (product name), Nippon Kayaku Co., Ltd.), 20 parts by mass of an indane-type maleimide compound (NE-X-9470S (product name), DIC corporation), 300 parts by mass of strontium titanate (SrTiO₃, an oxide of Perovskite structure, median particle size (D50): 0.3 μm, relative permittivity (Dk): 21, dissipation factor (Df): 0.007, ST-03 (product name), manufactured by SAKAI CHEMICAL INDUSTRY CO., LTD.), 3 parts by mass of a wetting and dispersing agent (BYK (registered trademark)-W903 (product name), manufactured by BYK Japan KK), 0.1 parts by mass of 2,4,5-triphenyl imidazole (manufactured by Tokyo Chemical Industry Co., Ltd.), 0.5 parts by mass of manganese octylate (Nikka Octhix Manganese (product name), manufactured by Nihon Kagaku Sangyo Co., Ltd.), and 100 parts by mass of methyl ethyl ketone.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 6

A resin varnish was obtained in the same manner as in Example 5, except that 40 parts by mass of the 1-naphthol aralkyl-type cyanate ester compound (SN495V-CN) obtained in Synthesis Example 1 was used instead of 45 parts by mass of the 1-naphthol aralkyl-type cyanate ester compound and 10 parts by mass of 1,3-phenylenebis(2,6-dixylenyl phosphate) (PX-200 (product name), Daihachi Chemical Industry Co., Ltd.) was used instead of 5 parts by mass of the 1,3-phenylenebis(2,6-dixylenyl phosphate).

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 7

A resin varnish was obtained in the same manner as in Example 5, except that 30 parts by mass of the 1-naphthol aralkyl-type cyanate ester compound (SN495V-CN) obtained in Synthesis Example 1 was used instead of 45 parts by mass of the 1-naphthol aralkyl-type cyanate ester compound and 20 parts by mass of 1,3-phenylenebis(2,6-dixylenyl phosphate) (PX-200 (product name), Daihachi Chemical Industry Co., Ltd.) was used instead of 5 parts by mass of the 1,3-phenylenebis(2,6-dixylenyl phosphate).

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 8

A resin varnish was obtained in the same manner as in Example 7, except that 20 parts by mass of condensed ester phosphate (SR-3000 (product name), Daihachi Chemical Industry Co., Ltd.) was used instead of 20 parts by mass of 1,3-phenylenebis(2,6-dixylenyl phosphate) (PX-200 (product name), Daihachi Chemical Industry Co., Ltd.).

Using this resin varnish, a prepreg and a metal foil-clad laminate were obtained in the same manner as in Example 1. Physical properties of the obtained prepreg and metal foil-clad laminate were measured in accordance with the evaluation methods, and the measurement results were shown in Table 1.

### Comparative Example 3

A resin varnish was obtained by mixing 50 parts by mass of the 1-naphthol aralkyl-type cyanate ester compound (SN495V-CN) obtained in Synthesis Example 1, 50 parts by mass of a biphenyl aralkyl-type maleimide compound (MIR-3000-70MT (product name), Nippon Kayaku Co., Ltd.), 300 parts by mass of strontium titanate (SrTiO₃, an oxide of Perovskite structure, median particle size (D50): 0.3 μm, relative permittivity (Dk): 21, dissipation factor (Df): 0.007, ST-03 (product name), manufactured by SAKAI CHEMICAL INDUSTRY CO., LTD.), 3 parts by mass of a wetting and dispersing agent (BYK (registered trademark)-W903 (product name), manufactured by BYK Japan KK), 0.1 parts by mass of 2,4,5-triphenyl imidazole (manufactured by Tokyo Chemical Industry Co., Ltd.), 0.5 parts by mass of manganese octylate (Nikka Octhix Manganese (product name), manufactured by Nihon Kagaku Sangyo Co., Ltd.), and 100 parts by mass of methyl ethyl ketone.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Example 9

A resin varnish was obtained by mixing 30 parts by mass of the 1-naphthol aralkyl-type cyanate ester compound (SN495V-CN) obtained in Synthesis Example 1, 50 parts by mass of an indane-type maleimide compound (NE-X-9470S (product name), DIC corporation), 20 parts by mass of 1,3-phenylenebis(2,6-dixylenyl phosphate) (PX-200 (product name), Daihachi Chemical Industry Co., Ltd.), 300 parts by mass of strontium titanate (SrTiO₃, an oxide of Perovskite structure, median particle size (D50): 0.3 μm, relative permittivity (Dk): 21, dissipation factor (Df): 0.007, ST-03 (product name), manufactured by SAKAI CHEMICAL INDUSTRY CO., LTD.), 3 parts by mass of a wetting and dispersing agent (BYK (registered trademark)-W903 (product name), manufactured by BYK Japan KK), 0.1 parts by mass of 2,4,5-triphenyl imidazole (manufactured by Tokyo Chemical Industry Co., Ltd.), 0.5 parts by mass of manganese octylate (Nikka Octhix Manganese (product name), manufactured by Nihon Kagaku Sangyo Co., Ltd.), and 100 parts by mass of methyl ethyl ketone.

Using this resin varnish, a prepreg and a metal foil-clad laminate were obtained in the same manner as in Example 1. Physical properties of the obtained prepreg, and metal foil-clad laminate were measured in accordance with the evaluation methods, and the measurement results were shown in Table 1.

### Evaluation Methods

### (1) Relative Permittivity (Dk) and Dissipation Factor (Df)

Four sheets of the prepregs obtained in Examples and Comparative Examples were laminated, and electrolytic copper foils (3EC-M3-VLP (product name), MITSUI MINING & SMELTING CO., LTD.) having a thickness of 12 m were disposed on the upper and lower sides thereof. The resultant was subjected to lamination forming by vacuum pressing at a surface pressure of 30 kgf/cm² and a temperature of 220° C. for 120 minutes, thereby manufacturing a metal foil-clad laminate (double-sided copper-clad laminated sheet) having a thickness of 0.424 mm. All the copper foils on both sides of the metal foil-clad laminates obtained in Examples and Comparative Examples were etched, thereby obtaining unclad laminates having a thickness of 0.4 mm from which all the copper foils on both sides were removed. The unclad laminate was cut (downsized) to a size of 1 mm×65 mm, thereby obtaining a sample for measurement. On this sample for measurement, the relative permittivity (Dk) and dissipation factor (Df) at 10 GHz were each measured using a network analyzer (Agilent (registered trademark) 8722ES (product name), manufactured by Agilent Technologies, Inc.). The measurement of the relative permittivity (Dk) and dissipation factor (Df) was carried out under the environment at a temperature of 23° C.±1° C., and a humidity of 50% RH±5% RH.

### (2) Copper Foil Peel Strength

Four sheets of the prepregs obtained in Examples and Comparative Examples were laminated, and electrolytic copper foils (3EC-M3-VLP (product name), manufactured by MITSUI MINING & SMELTING CO., LTD.) having a thickness of 12 μm were disposed on the upper and lower sides thereof. The resultant was subjected to lamination forming by vacuum pressing at a surface pressure of 30 kgf/cm² and a temperature of 220° C. for 120 minutes, thereby manufacturing a metal foil-clad laminate (a double-sided copper-clad laminated sheet) having a thickness of 0.424 mm. Using the metal foil-clad laminate (10 mm×100 mm×0.424 mm), the copper foil peel strength (copper foil close contact, kgf/cm) was measured in accordance with JIS C6481.

### (3) Moisture Absorption and Heat Resistance Evaluation

Each of the metal foil-clad laminates obtained in Examples and Comparative Examples was cut (downsized) to a size of 50 mm×50 mm. The copper foils on one side were all etched and removed, and on the other side the copper foil on a half of the surface was etched and removed, thereby manufacturing a sample for measurement.

The obtained sample for measurement was treated for 3 hours, using a pressure cooker test chamber (PC-3 type (product name), HIRAYAMA Manufacturing Corporation), at 121° C. and in the presence of saturated water vapor at 2 atmospheric pressure, and then dipped for 60 seconds in a solder bath at 260° C. to visually observe the presence or absence of abnormality in appearance changes.

For each of the measurement, 4 samples were tested, and the case where all 4 samples had no abnormality was rated as “A”, and the case where even 1 out of 4 samples had appearance abnormality was rated as “C”. In the case where, for example, swells were caused on the copper foil surface or the back of the sample after dipping, it was determined that the sample had appearance abnormality. In Tables 1 and 2, the “PCT 3 h” shows the results after the 3 hour-treatment using a pressure cooker test chamber.

### (4) Copper-Clad Solder Heat Resistance (Thermal Characteristics)

Each of the metal foil-clad laminates obtained in Examples and Comparative Examples was cut (downsized) to a size of 50 mm×50 mm, thereby obtaining a sample for measurement. Three samples for measurement in total were manufactured in the same manner. The samples for measurement were floated in a solder bath at 260° C. so that only one side of the sample contacted the solder for 30 minutes. Thirty minutes later, the sample was taken out of the solder bath to visually observe the side contacted the solder of these samples in terms of the presence or absence in appearance changes. Three samples were each observed. As a result, the case where all samples had no appearance abnormality was rated as “A”, and the case where 1 or more had appearance abnormality was rated as “C”. For example, when swells were found at the interface of the metal foil and the insulation layer in a sample, it was determined that the sample had appearance abnormality.

TABLE 1

| | | | | | Comparative | | | Comparative |
|---|---|---|---|---|---|---|---|---|
| | | | Example 1 | Example 2 | Example 1 | Example 3 | Example 4 | Example 2 |
| Various | Relative permittivity [Df, 10 GHz] | | 10.2 | 10.0 | 10.3 | 10.3 | 10.0 | 10.3 |
| physical | Dissipation factor [Df, 10 GHz] | | 0.0087 | 0.0081 | 0.0095 | 0.0048 | 0.0048 | 0.0059 |
| properties | Copper foil peel strength [kgf/cm] | | 0.87 | 0.83 | 0.95 | 0.82 | 0.74 | 0.82 |
| | Moisture | PCT 3 h | A | A | A | A | A | A |
| | absorption and | | | | | | | |
| | heat resistance | | | | | | | |
| | Copper-clad | Floating at 260° C. | A | A | A | A | A | A |
| | solder heat | for 30 minutes | | | | | | |
| | resistance | | | | | | | |

| | | | | | | | Comparative | Example |
|---|---|---|---|---|---|---|---|---|
| | | | Example 5 | Example 6 | Example 7 | Example 8 | Example 3 | 9 |
| Various | Relative permittivity [Df, 10 GHz] | | 10.4 | 10.5 | 10.6 | 10.3 | 10.7 | 9.6 |
| physical | Dissipation factor [Df, 10 GHz] | | 0.0056 | 0.0052 | 0.0048 | 0.0051 | 0.0058 | 0.0047 |
| properties | Copper foil peel strength [kgf/cm] | | 0.78 | 0.76 | 0.72 | 0.69 | 0.84 | 0.58 |
| | Moisture | PCT 3 h | A | A | A | A | A | A |
| | absorption and | | | | | | | |
| | heat resistance | | | | | | | |
| | Copper-clad | Floating at 260° C. | A | A | A | A | A | A |
| | solder heat | for 30 minutes | | | | | | |
| | resistance | | | | | | | |

The present application is based on the Japanese Patent Application (No. 2022-57895) filed on Mar. 31, 2022, and the contents of which are incorporated herein by reference.

### INDUSTRIAL APPLICABILITY

The resin composition of the present invention has a high permittivity and a low dissipation factor, and has excellent moisture absorption and heat resistance, a high glass transition temperature, a low coefficient of thermal expansion, and favorable coatability and appearance. Accordingly, the resin composition of the present invention can be suitably used, for example, as a material for a cured product, a prepreg, a film-like underfill material, a resin sheet, a laminate, a build-up material, a non-conductive film, a metal foil-clad laminate, a printed wiring board, and a fiber-reinforced composite material, or for producing a semiconductor device.

1. A resin composition comprising:
(A) a dielectric powder;
(B) an aromatic phosphorus compound; and
(C) a thermosetting resin.

2. The resin composition according to claim 1, wherein the dielectric powder (A) comprises one or more selected from the group consisting of titanium dioxide, barium titanate, calcium titanate, and strontium titanate.

3. The resin composition according to claim 1, wherein a median particle size of the dielectric powder (A) is 0.1 to 5 μm.

4. The resin composition according to claim 1, wherein a content of the dielectric powder (A) is 50 to 500 parts by mass, based on 100 parts by mass of a resin solid content in the resin composition.

5. The resin composition according to claim 1, wherein the aromatic phosphorus compound (B) comprises one or more selected from the group consisting of phosphaphenanthrene compounds, aromatic phosphorus compounds represented by the following formula (1), aromatic phosphorus compounds represented by the following formula (2), aromatic phosphorus compounds represented by the following formula (3), and aromatic phosphorus compounds represented by the following formula (4): 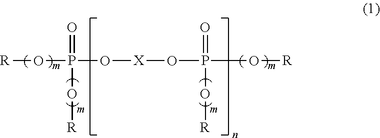
wherein R each independently represents a hydrogen atom, an alkyl group having 1 to 30 carbon atoms, or an aryl group having 6 to 30 carbon atoms, X represents a divalent organic group, m is each independently 0 or 1, and n is 0 to 5, provided that at least one R in the formula (1) is an aryl group having 6 to 30 carbon atoms; 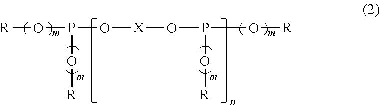
wherein R each independently represents a hydrogen atom, an alkyl group having 1 to 30 carbon atoms, or an aryl group having 6 to 30 carbon atoms, X represents a divalent organic group, m is each independently 0 or 1, and n is 0 to 5, provided that at least one R in the formula (2) is an aryl group having 6 to 30 carbon atoms; 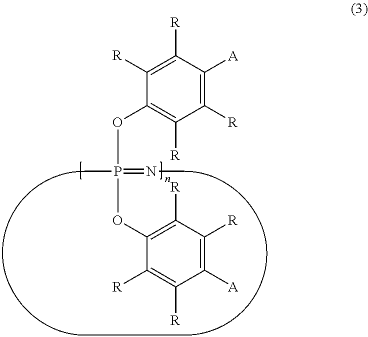
wherein A each independently represents a hydrogen atom, a hydroxy group, a cyano group, an amino group, a carboxy group, a glycidyloxy group, a para-hydroxyphenyl dimethyl group, a para-glycidyloxyphenyl dimethyl group, a para-hydroxyphenyl sulfone group, a para-glycidyloxyphenyl sulfone group, an alkyl group having 1 to 30 carbon atoms, an alkenyl group having 2 to 30 carbon atoms, or an aryl group having 6 to 30 carbon atoms, R each independently represents a hydrogen atom, an alkyl group having 1 to 30 carbon atoms, or an aryl group having 6 to 30 carbon atoms, and n represents an integer of 3 to 15; 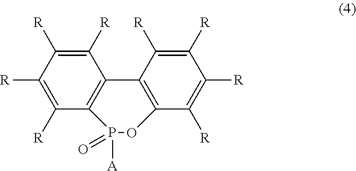
wherein A represents a hydrogen atom, a hydroxy group, a cyano group, an amino group, a carboxy group, a glycidyloxy group, a para-hydroxyphenyl dimethyl group, a para-glycidyloxyphenyl dimethyl group, a para-hydroxyphenyl sulfone group, a para-glycidyloxyphenyl sulfone group, an alkyl group having 1 to 30 carbon atoms, an alkenyl group having 2 to 30 carbon atoms, or an aryl group having 6 to 30 carbon atoms, and R each independently represents a hydrogen atom, an alkyl group having 1 to 30 carbon atoms, or an aryl group having 6 to 30 carbon atoms.

6. The resin composition according to claim 5, wherein the aromatic phosphorus compound represented by the formula (1) comprises one or more selected from the group consisting of aromatic phosphorus compounds represented by the following formula (6) and aromatic phosphorus compounds represented by the following formula (8): 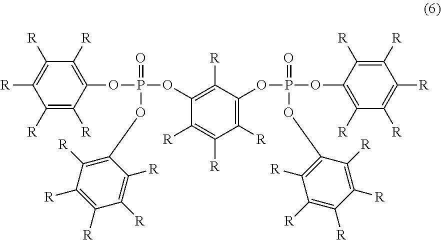
wherein R each independently represents a hydrogen atom, an alkyl group having 1 to 30 carbon atoms, or an aryl group having 6 to 30 carbon atoms; 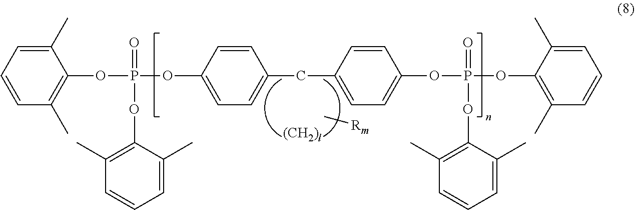
wherein R represents an alkyl group having 1 to 4 carbon atoms, l represents an integer of 3 to 11, m represents an integer of 0 to 22, and n represents an integer of 1 to 10.

7. The resin composition according to claim 1, wherein a content of the aromatic phosphorus compound (B) is 1 to 40 parts by mass, based on 100 parts by mass of a resin solid content in the resin composition.

8. The resin composition according to claim 1, wherein the thermosetting resin (C) comprises one or more selected from the group consisting of cyanate ester compounds, maleimide compounds, epoxy compounds, phenol compounds, modified polyphenylene ether compounds, alkenyl-substituted nadiimide compounds, oxetane resins, benzoxazine compounds, and compounds having a polymerizable unsaturated group.

9. The resin composition according to claim 8, wherein the maleimide compound comprises one or more selected from the group consisting of bis(4-maleimidephenyl)methane, 2,2-bis(4-(4-maleimidephenoxy)-phenyl)propane, bis(3-ethyl-5-methyl-4-maleimidephenyl)methane, maleimide compounds represented by the following formula (11), maleimide compounds represented by the following formula (12), and maleimide compounds represented by the following formula (13): 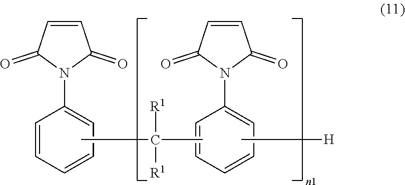
wherein R¹ each independently represents a hydrogen atom or a methyl group, and n1 is an integer of 1 to 10; 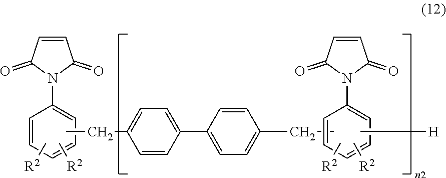
wherein R² each independently represents a hydrogen atom, an alkyl group having 1 to 5 carbon atoms, or a phenyl group, and n2 is an average value and represents 1<n2≤5; 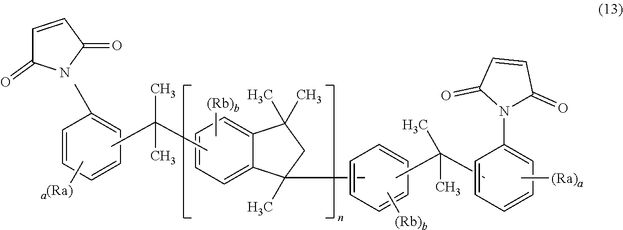
wherein Ra each independently represents an alkyl group, an alkyloxy group or an alkylthio group having 1 to 10 carbon atoms, an aryl group, an aryloxy group or an arylthio group having 6 to 10 carbon atoms, a cycloalkyl group having 3 to 10 carbon atoms, a halogen atom, a nitro group, a hydroxy group, or a mercapto group, q represents an integer of 0 to 4, and when q is an integer of 2 to 4, Ra can be the same or different in the same ring, Rb each independently represents an alkyl group, an alkyloxy group or an alkylthio group having 1 to 10 carbon atoms, an aryl group, an aryloxy group or an arylthio group having 6 to 10 carbon atoms, a cycloalkyl group having 3 to 10 carbon atoms, a halogen atom, a hydroxy group, or a mercapto group, r represents an integer of 0 to 3, and when r is 2 or 3, Rb can be the same or different in the same ring, and n is the average number of repeating units and represents a value of 0.95 to 10.0.

10. The resin composition according to claim 8, wherein a content of the maleimide compound is 15 to 85 parts by mass, based on 100 parts by mass of a resin solid content in the resin composition.

11. The resin composition according to claim 1, further comprising a filler different from the dielectric powder (A).

12. The resin composition according to claim 11, wherein the filler comprises one or more selected from the group consisting of silica, alumina, talc, aluminum nitride, boron nitride, boehmite, aluminum hydroxide, zinc molybdate, silicone rubber powder, and silicone composite powder.

13. The resin composition according to claim 11, wherein a content of the filler is 50 to 300 parts by mass, based on 100 parts by mass of a resin solid content in the resin composition.

14. The resin composition according to claim 1, wherein the resin composition is for a printed wiring board.

15. A prepreg comprising:
a base material, and
the resin composition according to claim 1 penetrating or coating the base material.

16. A resin sheet comprising the resin composition according to claim 1.

17. A laminate comprising the prepreg according to claim 15.

18. A laminate comprising the resin sheet according to claim 16.

19. A metal foil-clad laminate comprising:
the laminate according to claim 17, and
a metal foil disposed on one side or each of both sides of the laminate.

20. A metal foil-clad laminate comprising:
the laminate according to claim 18, and
a metal foil disposed on one side or each of both sides of the laminate.

21. A printed wiring board, comprising:
an insulation layer, and
a conductor layer disposed on one side or each of both sides of the insulation layer,
wherein the insulation layer comprises a cured product of the resin composition according to claim 1.
